(19) United States
(12) Patent Application Publication
(10) Pub. No.: US 2026/0282390 A1
(43) Pub. Date: Sep. 17, 2026

(54) STORAGE DEVICE

(71) Applicant: Kioxia Corporation, Tokyo (JP)

(72) Inventor: Kenta CHOKAWA, Yokohama Kanagawa (JP)

(21) Appl. No.: 19/315,325

(22) Filed: Aug. 29, 2025

(30) Foreign Application Priority Data
Mar. 14, 2025 (JP) 2025-041532

(51) Int. Cl. H10B 63/00; H10B 61/00

(52) U.S. Cl. CPC H10B 63/22; H10B 61/10

(57) ABSTRACT

A storage device includes first through third electrodes and switching and resistive layers. The second electrode is between the first and third electrodes. The switching layer is between the first and second electrodes. The resistive layer is between the second and third electrodes. The switching layer includes: an oxide, a nitride, or an oxynitride of a first element selected from a group consisting of aluminum, silicon, germanium, zirconium, yttrium, tantalum, lanthanum, cerium, titanium, hafnium, and magnesium, a second element is selected from a group consisting of aluminum, zinc, tin, gallium, bismuth, and indium, and a third element selected from a group consisting of tellurium, sulfur, selenium, and antimony. One of the first and second electrodes includes a carbon layer including a first region that contacts the switching layer and includes one fourth element selected from a group consisting of silicon, aluminum, phosphorus, gallium, and germanium.

### CROSS-REFERENCE TO RELATED APPLICATIONS

This application is based upon and claims the benefit of priority from Japanese Patent Application No. 2025-041532, filed Mar. 14, 2025, the entire contents of which are incorporated herein by reference.

### FIELD

Embodiments described herein relate generally to a storage device.

### BACKGROUND

Large-capacity non-volatile storage devices include, for example, cross-point two-terminal storage devices. Such cross-point two-terminal storage devices facilitate the fabrication of finer, more highly integrated memory cells.

### BRIEF DESCRIPTION OF THE DRAWINGS

FIG. 1 is a block diagram of a storage device in a first embodiment.

FIG. 2 is a schematic sectional view of a memory cell of the storage device in the first embodiment.

FIG. 3 is a diagram illustrating an operation of the storage device in the first embodiment.

FIG. 4 is a diagram illustrating the current-voltage characteristics of a switching element in the first embodiment.

FIG. 5 is a schematic sectional view of a memory cell of a storage device in a comparative example.

FIG. 6 is a schematic sectional view of a memory cell of a storage device in a first modification of the first embodiment.

FIG. 7 is a schematic sectional view of a memory cell of a storage device in a second modification of the first embodiment.

FIG. 8 is a schematic sectional view of a memory cell of a storage device in a third modification of the first embodiment.

FIG. 9 is a schematic sectional view of a memory cell of a storage device in a fourth modification of the first embodiment.

FIG. 10 is a schematic sectional view of a memory cell of a storage device in a second embodiment.

FIG. 11 is a schematic sectional view of a memory cell of a storage device in a third embodiment.

FIG. 12 is a schematic sectional view of a memory cell of a storage device in a fourth embodiment.

FIG. 13 is a schematic sectional view of a memory cell of a storage device in a fifth embodiment.

FIG. 14 is a schematic sectional view of the memory cell of a storage device in a sixth embodiment.

FIG. 15 is a diagram illustrating the current-voltage characteristics of a memory element in the sixth embodiment.

FIG. 16 is a diagram illustrating a first operation example of memory operation of the storage device in the sixth embodiment.

FIG. 17 is a diagram illustrating a second operation example of memory operation of the storage device in the sixth embodiment.

FIG. 18 is a diagram illustrating the current-voltage characteristics of a memory element in a first modification of the sixth embodiment.

FIG. 19 is a diagram illustrating a third operation example of memory operation of the storage device in the first modification of the sixth embodiment.

FIG. 20 is a diagram illustrating a fourth operation example of memory operation of the storage device in the first modification of the sixth embodiment.

FIG. 21 is a diagram illustrating the current-voltage characteristics of a memory element in a second modification of the sixth embodiment.

FIG. 22 is a diagram illustrating a fifth operation example of memory operation of the storage device in the second modification of the sixth embodiment.

FIG. 23 is a diagram illustrating a sixth operation example of memory operation of the storage device in the second modification of the sixth embodiment.

FIG. 24 is a diagram illustrating the current-voltage characteristics of a memory element in a third modification of the sixth embodiment.

FIG. 25 is a diagram illustrating a seventh operation example of memory operation of the storage device in the third modification of the sixth embodiment.

FIG. 26 is a diagram illustrating an eighth operation example of memory operation of the storage device in the third modification of the sixth embodiment.

### DETAILED DESCRIPTION

Embodiments of the present disclosure provide a storage device having excellent characteristics.

In general, according to one embodiment, a storage device comprises a plurality of memory cells each including a first electrode, a second electrode, a third electrode, a switching layer, and a resistive layer. The second electrode is between the first and third electrodes, the switching layer is between the first and second electrodes, and the resistive layer is between the second and third electrodes. The switching layer includes: an oxide, a nitride, or an oxynitride of at least one first element selected from a group consisting of aluminum, silicon, germanium, zirconium, yttrium, tantalum, lanthanum, cerium, titanium, hafnium, and magnesium, at least one second element that is different from the first element and is selected from a group consisting of aluminum, zinc, tin, gallium, bismuth, and indium, and at least one third element selected from a group consisting of tellurium, sulfur, selenium, and antimony. At least one of the first and second electrodes includes a carbon layer, and the carbon layer includes a first region that contacts the switching layer and includes at least one fourth element selected from a group consisting of silicon, aluminum, phosphorus, gallium, and germanium.

Hereinafter, embodiments of the present invention will be described with reference to the drawings. Note that in the following description, the same or similar elements are assigned the same symbols, and description of elements and the like having been described once will not be repeated as appropriate.

For example, Rutherford backscattering spectroscopy (RBS), secondary ion mass spectroscopy (SIMS), energy dispersive X-ray spectroscopy (EDS), or electron energy loss spectroscopy (EELS) can be used for qualitative analysis and quantitative analysis of chemical compositions constituting a storage device in the present Specification. To measure the thicknesses of elements constituting the storage device, the distances between the components and the like, for example, a transmission electron microscope (TEM) can be used. To identify the constitutive substances of the elements making up the storage device, measure the presence rates of the constitutive substances, identify the bonding states of the constitutive substances, identify the local structures (e.g., atomic arrangements, atomic distances, and coordination numbers) of the constitutive substances, measure the chemical state of the constitutive substances, and compare the concentrations of the constitutive substances, for example, X-ray photoelectron spectroscopy (XPS), X-ray absorption fine structure (XAFS), Raman spectroscopy (Raman), scanning transmission electron microscope (STEM), or EELS can be used.

The atomic concentration in the present Specification is represented by atomic composition percentage (at %).

### First Embodiment

A storage device in a first embodiment includes a memory cell that includes a first electrode, a second electrode, a third electrode, a switching layer, and a resistive layer. The second electrode is provided between the first electrode and the third electrode, the switching layer is provided between the first electrode and the second electrode, and the resistive layer is provided between the second electrode and the third electrode. The switching layer contains: an oxide, a nitride, or an oxynitride of at least one first element selected from a group consisting of aluminum (Al), silicon (Si), germanium (Ge), zirconium (Zr), yttrium (Y), tantalum (Ta), lanthanum (La), cerium (Ce), titanium (Ti), hafnium (Hf), and magnesium (Mg); at least one second element that is different from the first element and is selected from a group consisting of aluminum (Al), zinc (Zn), tin (Sn), gallium (Ga), bismuth (Bi), and indium (In); and at least one third element selected from a group consisting of tellurium (Te), sulfur (S), selenium (Se), and antimony (Sb). At least one electrode selected from the first electrode and the second electrode includes a carbon layer. The carbon layer includes a first region that is in contact with the switching layer, and contains at least a fourth element selected from a group consisting of silicon (Si), aluminum (Al), phosphorus (P), gallium (Ga), and germanium (Ge).

The storage device in the first embodiment further includes a plurality of first lines, and a plurality of second lines that intersect the plurality of first lines. The memory cell is provided in a region where one of the plurality of first lines intersects one of the plurality of second lines.

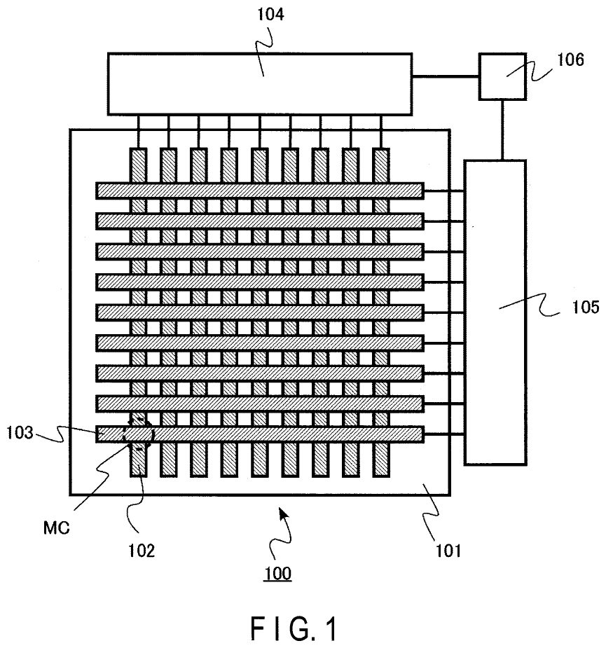

FIG. 1 is a block diagram of the storage device in the first embodiment.

A memory cell array 100 of the storage device in the first embodiment includes, for example, a plurality of word lines 102, and a plurality of bit lines 103 that intersect the word lines 102, via an insulating layer, on a semiconductor substrate 101. The bit lines 103 are provided on an upper layer of the word lines 102. A first control circuit 104, a second control circuit 105, and a sense circuit 106 are provided, as peripheral circuits, around the memory cell array 100.

The word lines 102 are also referred to as the first lines. The bit lines 103 are also referred to as the second lines.

A plurality of memory cells MC are respectively provided in regions where the word lines 102 intersect the bit lines 103. The storage device in the first embodiment is a two-terminal magnetoresistive memory that has a cross-point structure.

Each of the word lines 102 is connected to the first control circuit 104. Each of the bit lines 103 is connected to the second control circuit 105. The sense circuit 106 is connected to the first control circuit 104 and the second control circuit 105.

The first control circuit 104 and the second control circuit 105 have, for example, functions such as of selecting a desired memory cell MC, writing data into the memory cell MC, reading data from the memory cell MC, and erasing data in the memory cell MC. When data is read, the data in the memory cell MC is read as an amount of current flowing between the word line 102 and the bit line 103, or a change in potential on the bit line 103. The sense circuit 106 has functions of determining the amount of current or change in potential, and determining the polarity of the data. For example, it is determined whether the data is “0” or “1”.

The first control circuit 104, the second control circuit 105, and the sense circuit 106 are made up of, for example, electronic circuits using semiconductor devices formed on the semiconductor substrate 101.

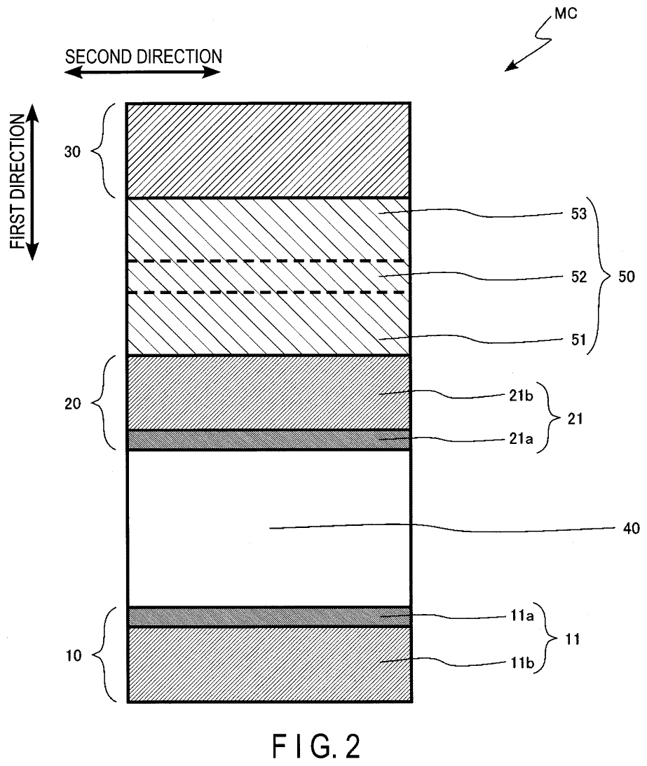

FIG. 2 is a schematic sectional view of the memory cell of the storage device in the first embodiment. FIG. 2 shows a section of one memory cell MC indicated by, for example, a broken-line circle in the memory cell array 100 in FIG. 1. FIG. 2 shows a section in parallel with a first direction that connects a first electrode 10 and a second electrode 20.

As shown in FIG. 2, the memory cell MC includes the first electrode 10, the second electrode 20, a third electrode 30, a switching layer 40, and a resistive layer 50. The first electrode 10 includes a first carbon layer 11. The second electrode 20 includes a second carbon layer 21. The first carbon layer 11 includes a first high-concentration region 11a and a first low-concentration region 11b. The second carbon layer 21 includes a second high-concentration region 21a and a second low-concentration region 21b.

Each of the first carbon layer 11 and the second carbon layer 21 is also referred to as the carbon layer. Each of the first high-concentration region 11a and the second high-concentration region 21a is also referred to as the first region. Each of the first low-concentration region 11b and the second low-concentration region 21b is also referred to as the second region.

The first electrode 10, the switching layer 40, and the second electrode 20 constitute a switching element of the memory cell MC. The second electrode 20, the resistive layer 50, and the third electrode 30 constitute a resistive element of the memory cells MC.

The first electrode 10 is connected to the word line 102. The first electrode 10 includes the first carbon layer 11.

The first carbon layer 11 is graphite, for example. The first carbon layer 11 is amorphous, for example. The first carbon layer 11 contains, for example, six-membered carbon ring structures. The atomic concentration of carbon (C) contained in the first carbon layer 11 ranges, for example, between 80 at % and 100 at %, inclusive.

The first electrode 10 is in contact with the switching layer 40. The first carbon layer 11 is in contact with the switching layer 40.

The first carbon layer 11 includes the first high-concentration region 11a and the first low-concentration region 11b. The first high-concentration region 11a is provided between the first low-concentration region 11b and the switching layer 40. The first high-concentration region 11a is in contact with the switching layer 40.

The first high-concentration region 11a contains at least one fourth element selected from a group consisting of silicon (Si), aluminum (Al), phosphorus (P), gallium (Ga), and germanium (Ge). The first low-concentration region 11b contains or does not contain the fourth element.

The atomic concentration of the fourth element in the first low-concentration region 11b is lower than the atomic concentration of the fourth element in the first high-concentration region 11a.

The ratio of the atomic concentration of the fourth element to the sum of the atomic concentration of carbon (C) and the atomic concentration of the fourth element in the first high-concentration region 11a ranges between, for example, 1% and 20%, inclusive. The ratio of the atomic concentration of the fourth element to the sum of the atomic concentration of carbon (C) and the atomic concentration of the fourth element in the first low-concentration region 11b ranges between, for example, 0% and 5%, inclusive.

The first high-concentration region 11a is graphite, for example. The first high-concentration region 11a is amorphous, for example. The first high-concentration region 11a contains, for example, six-membered carbon ring structures.

The thickness of the first high-concentration region 11a in the first direction from the first electrode 10 toward the second electrode 20 is less than the thickness of the first low-concentration region 11b in the first direction. The thickness of the first high-concentration region 11a in the first direction ranges between, for example, 0.1 nm and 1 nm, inclusive.

The first electrode 10 can be formed using, for example, the co-sputtering method using a plurality of targets. For example, a first carbon target formed of carbon to which the fourth element is added, and a second carbon target formed of carbon to which no fourth element is added are used.

By controlling the sputtering amount for the first target and the sputtering amount for the second target, the first high-concentration region 11a and the first low-concentration region 11b that have different atomic concentrations of the fourth element can be sequentially formed. Through use of the first carbon target to which the fourth element is added, for example, the fourth element can be evenly distributed in the first high-concentration region 11a.

The second electrode 20 is provided between the first electrode 10 and the third electrode 30. The second electrode 20 includes a second carbon layer 21.

The second carbon layer 21 is graphite, for example. The second carbon layer 21 is amorphous, for example. The second carbon layer 21 contains, for example, six-membered carbon ring structures. The atomic concentration of carbon (C) contained in the second carbon layer 21 ranges, for example, between 80 at % and 100 at %, inclusive.

The second electrode 20 is in contact with the switching layer 40. The second carbon layer 21 is in contact with the switching layer 40.

The second carbon layer 21 includes a second high-concentration region 21a and a second low-concentration region 21b. The second high-concentration region 21a is provided between the second low-concentration region 21b and the switching layer 40. The second high-concentration region 21a is in contact with the switching layer 40.

The second high-concentration region 21a contains at least one fourth element selected from a group consisting of silicon (Si), aluminum (Al), phosphorus (P), gallium (Ga), and germanium (Ge). The second low-concentration region 21b contains or does not contain the fourth element.

The atomic concentration of the fourth element in the second low-concentration region 21b is lower than the atomic concentration of the fourth element in the second high-concentration region 21a.

The ratio of the atomic concentration of the fourth element to the sum of the atomic concentration of carbon (C) and the atomic concentration of the fourth element in the second high-concentration region 21a ranges between, for example, 1% and 20%, inclusive. The ratio of the atomic concentration of the fourth element to the sum of the atomic concentration of carbon (C) and the atomic concentration of the fourth element in the second low-concentration region 21b ranges between, for example, 0% and 5%, inclusive.

The second high-concentration region 21a is graphite, for example. The second high-concentration region 21a is amorphous, for example. The second high-concentration region 21a contains, for example, six-membered carbon ring structures.

The thickness of the second high-concentration region 21a in the first direction from the first electrode 10 toward the second electrode 20 is less than the thickness of the second low-concentration region 21b in the first direction. The thickness of the second high-concentration region 21a in the first direction ranges between, for example, 0.1 nm and 1 nm, inclusive.

The second electrode 20 can be formed by a method similar to that for the first electrode 10.

The third electrode 30 is connected to the bit line 103. The third electrode 30 is made of metal, for example. The third electrode 30 contains, for example, at least one substance selected from a group consisting of carbon, carbon nitride, tungsten, tungsten carbide, tungsten nitride, titanium, titanium nitride, tantalum, tantalum carbide, and tantalum nitride. The third electrode 30 may be part of the bit line 103.

The switching layer 40 is provided between the first electrode 10 and the second electrode 20. The thickness of the switching layer 40 in the first direction from the first electrode 10 toward the second electrode 20 ranges between, for example, 4 nm and 25 nm, inclusive. The length of the switching layer 40 in a second direction perpendicular to the first direction ranges between, for example, 10 nm and 50 nm, inclusive.

The switching layer 40 has a function of preventing increase in semi-selected leakage current that flows through a semi-selected cell. The switching layer 40 has nonlinear current-voltage characteristics in which the current steeply rises at a specific threshold voltage.

The switching layer 40 contains a first oxide, a nitride, or an oxynitride of the first element. The switching layer 40 contains the second element and the third element. The switching layer 40 contains at least one of oxygen (O) or nitrogen (N).

The first element is at least one element selected from a group consisting of aluminum (Al), silicon (Si), germanium (Ge), zirconium (Zr), yttrium (Y), tantalum (Ta), lanthanum (La), cerium (Ce), titanium (Ti), hafnium (Hf), and magnesium (Mg).

The oxide of the first element is, for example, aluminum oxide, silicon oxide, germanium oxide, zirconium oxide, yttrium oxide, tantalum oxide, lanthanum oxide, cerium oxide, titanium oxide, hafnium oxide, or magnesium oxide. The nitride of the first element is, for example, aluminum nitride, silicon nitride, germanium nitride, zirconium nitride, yttrium nitride, tantalum nitride, lanthanum nitride, cerium nitride, titanium nitride, hafnium nitride, or magnesium nitride. The oxynitride of the first element is, for example, aluminum oxynitride, silicon oxynitride, germanium oxynitride, zirconium oxynitride, yttrium oxynitride, tantalum oxynitride, lanthanum oxynitride, cerium oxynitride, titanium oxynitride, hafnium oxynitride, or magnesium oxynitride.

The second element is an element that is different from the first element. The second element is at least one element selected from a group consisting of aluminum (Al), zinc (Zn), tin (Sn), gallium (Ga), bismuth (Bi), and indium (In). The third element is at least one element selected from a group consisting of tellurium (Te), sulfur (S), selenium (Se), and antimony (Sb).

The switching layer 40 contains, for example, a compound of the second element and the third element. The compound of the second element and the third element is, for example, aluminum telluride, zinc telluride, tin telluride, gallium telluride, bismuth telluride, indium telluride, aluminum sulfide, zinc sulfide, tin sulfide, gallium sulfide, bismuth sulfide, indium sulfide, aluminum selenide, zinc selenide, tin selenide, gallium selenide, bismuth selenide, indium selenide, aluminum antimonide, zinc antimonide, tin antimonide, gallium antimonide, bismuth antimonide, or indium antimonide.

The sum of the atomic concentration of the first element, the atomic concentration of the second element, the atomic concentration of the third element, the atomic concentration of oxygen (O), and the atomic concentration of nitrogen (N) in the switching layer 40 is called the total concentration. The total concentration in the switching layer 40 ranges between, for example, 80 at % and 100 at %, inclusive.

The switching layer 40 contains, for example, carbon (C), boron (B), or phosphorus (P).

The resistive layer 50 is provided between the second electrode 20 and the third electrode 30. The resistive layer 50 includes the fixed layer 51, the tunnel layer 52, and the free layer 53. The resistive layer 50 includes a magnetic tunnel junction made up of the fixed layer 51, the tunnel layer 52, and the free layer 53.

The resistive layer 50 has a function of storing data by resistance change. The resistive layer 50 has, for example, characteristics in which the electrical resistance changes with application of a predetermined voltage.

The fixed layer 51 is a ferromagnetic body. In the fixed layer 51, the magnetization direction does not change with a predetermined write voltage, and the magnetization direction is fixed in a specific direction.

The tunnel layer 52 is an insulator. In the tunnel layer 52, electrons pass by the tunneling effect.

The free layer 53 is a ferromagnetic body. In the free layer 53, the magnetization direction changes with the predetermined write voltage. The magnetization direction of the free layer 53 can be in any of states that are a state parallel with the magnetization direction of the fixed layer 51 and a state antiparallel with the magnetization direction of the fixed layer 51. For example, by applying a voltage and causing current to flow between the second electrode 20 and the third electrode 30, the magnetization direction of the free layer 53 can be changed.

By changing the magnetization direction of the free layer 53, the electrical resistance of the resistive layer 50 changes. When the magnetization direction of the free layer 53 is in the state antiparallel with the magnetization direction of the fixed layer 51, a high-resistance state in which it is difficult for the current to flow is achieved. In contrast, when the magnetization direction of the free layer 53 is in the state parallel with the magnetization direction of the fixed layer 51, a low-resistance state in which the current easily flows is achieved. Note that the arrangement of the fixed layer 51 and the free layer 53 may be inverted. That is, the second electrode 20, the free layer 53, the tunnel layer 52, the fixed layer 51, and the third electrode 30 may be stacked in this order.

Next, the operation and advantageous effects of the storage device in the first embodiment will be described.

As described above, in the storage device in the first embodiment, by changing the magnetization direction of the free layer 53, the resistance of the resistive layer 50 changes. When the magnetization direction of the free layer 53 is in the state antiparallel with the magnetization direction of the fixed layer 51, the high-resistance state in which it is difficult for the current to flow is achieved. In contrast, when the magnetization direction of the free layer 53 is in the state parallel with the magnetization direction of the fixed layer 51, the low-resistance state in which the current easily flows is achieved.

For example, the high-resistance state of the resistive layer 50 is defined as data “1”, and the low-resistance state is defined as data “0”. The memory cell MC can maintain the different resistance states, thus allowing one-bit data of “0” and “1” to be stored. Writing into one memory cell MC is performed by applying a voltage and causing current to flow between the bit line 103 and the word line 102 that are connected to the memory cell MC.

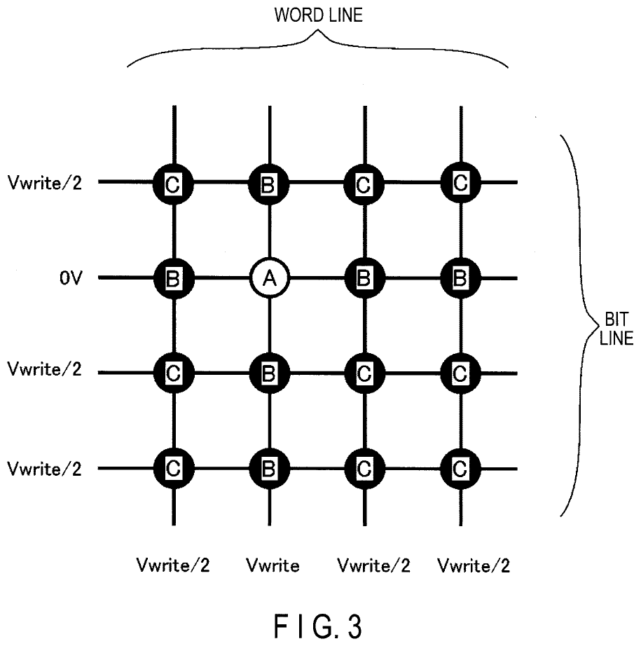

FIG. 3 is a diagram illustrating an operation of the storage device in the first embodiment. FIG. 3 shows the voltage applied to one memory cell MC of the memory cell array selected for a write operation. The intersections of the word lines and the bit lines indicate the selected and non-selected memory cells MC.

The selected memory cell MC is a memory cell A (hereinafter also referred to as the selected cell). A write voltage Vwrite is applied to the word line connected to the memory cell A. 0 V is applied to the bit line connected to the memory cell A.

Hereinafter, description is made using an example in which a half voltage of the write voltage (Vwrite/2) is applied to word lines and bit lines that are not connected to the memory cell A.

The voltage applied to memory cells C (hereinafter also referred to as the unselected cells) connected to the word lines and the bit lines that are not connected to the memory cell A is 0 V. That is, no voltage is applied.

On the other hand, the half voltage of the write voltage Vwrite (Vwrite/2) is applied to memory cells B (hereinafter also referred to as the semi-selected cells) connected to the word lines or the bit lines connected to the memory cell A. Consequently, semi-selected leakage current flows through the memory cells B (i.e., the semi-selected cells).

Note that as an application scheme other than the above, a scheme may be used that applies the half voltage of the write voltage (Vwrite/2) to the word line connected to the memory cell A, applies the half negative voltage of the write voltage (−Vwrite/2) to the bit line, and applies 0 V to word lines and bit lines that are not connected to the memory cell A.

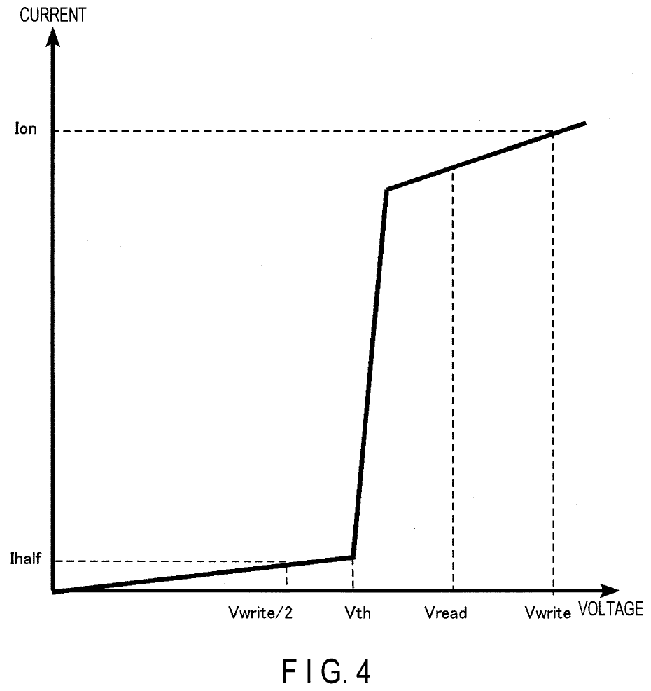

FIG. 4 is a diagram illustrating the current-voltage characteristics of the switching element in the first embodiment. The abscissa axis indicates the voltage applied to the switching element, and the ordinate axis indicates the current flowing through the switching element.

The switching element has nonlinear current-voltage characteristics in which the current steeply rises at a threshold voltage Vth. The threshold voltage Vth ranges, for example, between 0.5 V and 3 V, inclusive.

The write voltage Vwrite is set such that the write voltage Vwrite is higher than the threshold voltage Vth, and the half voltage of the write voltage Vwrite (Vwrite/2) is lower than the threshold voltage. The current flowing through the switching element when the write voltage Vwrite is applied is an on-state current (Ion in FIG. 4). The current flowing through the switching element when the half voltage of the write voltage Vwrite (Vwrite/2) is applied is the semi-selected leakage current (Ihalf in FIG. 4).

Note that for example, as shown in FIG. 4, a read voltage Vread to the memory cell MC is set to a voltage higher than the threshold voltage Vth and lower than the write voltage Vwrite. Consequently, the semi-selected leakage current flowing through the semi-selected cells during reading from the memory cell MC can also be prevented.

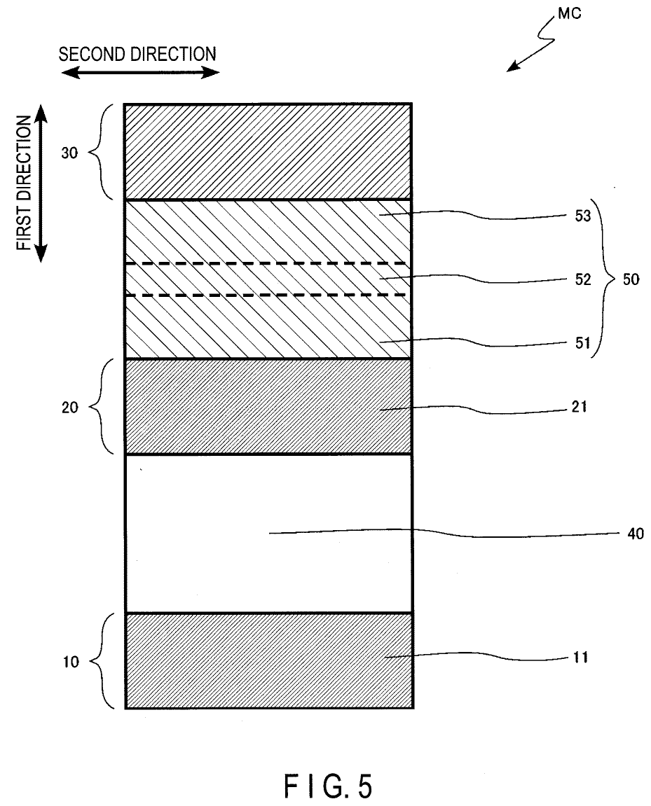

FIG. 5 is a schematic sectional view of a memory cell of a storage device in a comparative example. FIG. 5 is a diagram corresponding to FIG. 2 in the first embodiment.

The memory cell MC of the storage device in the comparative example is different from the memory cell MC in the first embodiment in that the first carbon layer 11 of the first electrode 10 does not include the first high-concentration region 11a. The memory cell MC of the storage device in the comparative example is different from the memory cell MC in the first embodiment in that the second carbon layer 21 of the second electrode 20 does not include the second high-concentration region 21a.

In the memory cell MC of the storage device in the comparative example, peeling may occur on the interface between the first electrode 10 and the switching layer 40, or the interface between the second electrode 20 and the switching layer 40. If peeling occurs on the interface between the electrode and the switching layer 40, there is, for example, a possibility that the electrical resistance between the electrode and the switching layer 40 increases, and the memory cell MC does not operate.

It is conceivable that a cause of occurrence of peeling on the interface in the memory cell MC of the storage device in the comparative example is the small number of bonds formed by covalent bonding between the atoms constituting the electrode and the atoms constituting the switching layer 40. Since the number of bonds formed by covalent bonding between the atoms constituting the electrode and the atoms constituting the switching layer 40 is small, it is conceivable that the adhesiveness between the electrode and the switching layer 40 is low.

The carbon layer of the electrode is mainly formed of graphite. The graphite has a structure with stacked layers of connected six-membered carbon rings. In the graphite, carbon atoms are covalently bonded with sp2 bonding. The stacked layers are bonded only by the van der Waals force instead of the covalent bonding. The bonding force between the layers is weak.

The graphite has sp2 bonds on the interface between the electrode and the switching layer 40. Accordingly, it is conceivable that the number of bonds formed by covalent bonding between the carbon atoms constituting the electrode and the atoms constituting the switching layer 40 is small, and the adhesiveness between the electrode and the switching layer 40 is low.

In the memory cell MC in the first embodiment, the first carbon layer 11 of the first electrode 10 includes the first high-concentration region 11a. The first high-concentration region 11a is in contact with the switching layer 40, and contains at least one fourth element selected from a group consisting of silicon (Si), aluminum (Al), phosphorus (P), gallium (Ga), and germanium (Ge).

The fourth element tends to form sp3 bonds. Accordingly, if the element is contained in the graphite, the coordination number of the carbon atom increases. Thus, since the first high-concentration region 11a contains the fourth element, the number of bonds formed by covalent bonding between the atoms contained in the switching layer 40 and the carbon atoms in the first carbon layer 11 increases. Consequently, the adhesiveness between the first electrode 10 and the switching layer 40 becomes high. Therefore, the interface between the first electrode 10 and the switching layer 40 is prevented from peeling.

The fourth element tends to form covalent bonds with oxygen atoms or nitrogen atoms contained in the switching layer 40. Furthermore, the fourth element tends to form the covalent bonds with carbon atoms contained in the first carbon layer 11. Consequently, the number of bonds formed by covalent bonding between the oxygen atoms or nitrogen atoms contained in the switching layer 40 and the carbon atoms in the first carbon layer 11 via the fourth element increases. Consequently, the adhesiveness between the first electrode 10 and the switching layer 40 becomes high. Therefore, the interface between the first electrode 10 and the switching layer 40 is prevented from peeling.

In the memory cell MC in the first embodiment, the second carbon layer 21 of the second electrode 20 includes the second high-concentration region 21a. The second high-concentration region 21a is in contact with the switching layer 40, and contains at least one fourth element selected from a group consisting of silicon (Si), aluminum (Al), phosphorus (P), gallium (Ga), and germanium (Ge). Consequently, because of a reason similar to that in the case of the first electrode 10 and the switching layer 40, the interface between the second electrode 20 and the switching layer 40 is prevented from peering.

In the memory cell MC in the first embodiment, the first carbon layer 11 of the first electrode 10 includes the first low-concentration region 11b. The atomic concentration of the fourth element in the first low-concentration region 11b is lower than the atomic concentration of the fourth element in the first high-concentration region 11a.

If the fourth element is contained in the carbon layer, the electrical resistance of the carbon layer becomes high. By including the first low-concentration region 11b in the first carbon layer 11, the electrical resistance of the first carbon layer 11 can be prevented from increasing. Consequently, the first electrode 10 having a low electrical resistance can be realized.

In the memory cell MC in the first embodiment, the second carbon layer 21 of the second electrode 20 includes the second low-concentration region 21b. The atomic concentration of the fourth element in the second low-concentration region 21b is lower than the atomic concentration of the fourth element in the second high-concentration region 21a. Consequently, because of a reason similar to that for the first electrode 10, the second electrode 20 having a low electrical resistance can be achieved.

In view of preventing the interface between the first electrode 10 and the switching layer 40 from peeling, it is preferable that the ratio of the atomic concentration of the fourth element to the sum of the atomic concentration of carbon (C) and the atomic concentration of the fourth element in the first high-concentration region 11a be higher than or equal to 1%, more preferably, higher than or equal to 5%, and further preferably, higher than or equal to 8%.

In view of reducing the electrical resistance of the first electrode 10, it is preferable that the ratio of the atomic concentration of the fourth element to the sum of the atomic concentration of carbon (C) and the atomic concentration of the fourth element in the first high-concentration region 11a be less than or equal to 20%, more preferably, less than or equal to 15%, and further preferably, less than or equal to 12%.

In view of preventing the interface between the first electrode 10 and the switching layer 40 from peeling, it is preferable that the thickness of the first high-concentration region 11a in the first direction be more than or equal to 0.1 nm, and more preferably, more than or equal to 0.3 nm.

In view of reducing the electrical resistance of the first electrode 10, it is preferable that the thickness of the first high-concentration region 11a in the first direction be less than or equal to 1 nm, and more preferably, less than or equal to 0.8 nm.

In view of reducing the electrical resistance of the first electrode 10, it is preferable that the ratio of the atomic concentration of the fourth element to the sum of the atomic concentration of carbon (C) and the atomic concentration of the fourth element in the first low-concentration region 11b be less than or equal to 5%, more preferably, less than or equal to 3%, and further preferably, less than or equal to 1%.

In view of preventing the interface between the second electrode 20 and the switching layer 40 from peeling, it is preferable that the ratio of the atomic concentration of the fourth element to the sum of the atomic concentration of carbon (C) and the atomic concentration of the fourth element in the second high-concentration region 21a be higher than or equal to 1%, more preferably, higher than or equal to 5%, and further preferably, higher than or equal to 8%.

In view of reducing the electrical resistance of the second electrode 20, it is preferable that the ratio of the atomic concentration of the fourth element to the sum of the atomic concentration of carbon (C) and the atomic concentration of the fourth element in the second high-concentration region 21a be less than or equal to 20%, more preferably, less than or equal to 15%, and further preferably, less than or equal to 12%.

In view of preventing the interface between the second electrode 20 and the switching layer 40 from peeling, it is preferable that the thickness of the second high-concentration region 21a in the first direction be more than or equal to 0.1 nm, and more preferably, more than or equal to 0.3 nm.

In view of reducing the electrical resistance of the second electrode 20, it is preferable that the thickness of the second high-concentration region 21a in the first direction be less than or equal to 1 nm, and more preferably, less than or equal to 0.8 nm.

In view of reducing the electrical resistance of the second electrode 20, it is preferable that the ratio of the atomic concentration of the fourth element to the sum of the atomic concentration of carbon (C) and the atomic concentration of the fourth element in the second low-concentration region 21b be less than or equal to 5%, more preferably, less than or equal to 3%, and further preferably, less than or equal to 1%.

According to the first embodiment, the switching element where the peeling on the interface between the first electrode 10 and the switching layer 40, and the peeling on the interface between the second electrode 20 and the switching layer 40 are prevented can be realized. Consequently, the storage device having excellent characteristics can be realized.

### First Modification

A storage device in a first modification of the first embodiment is different from the storage device in the first embodiment in that the first electrode includes no carbon layer.

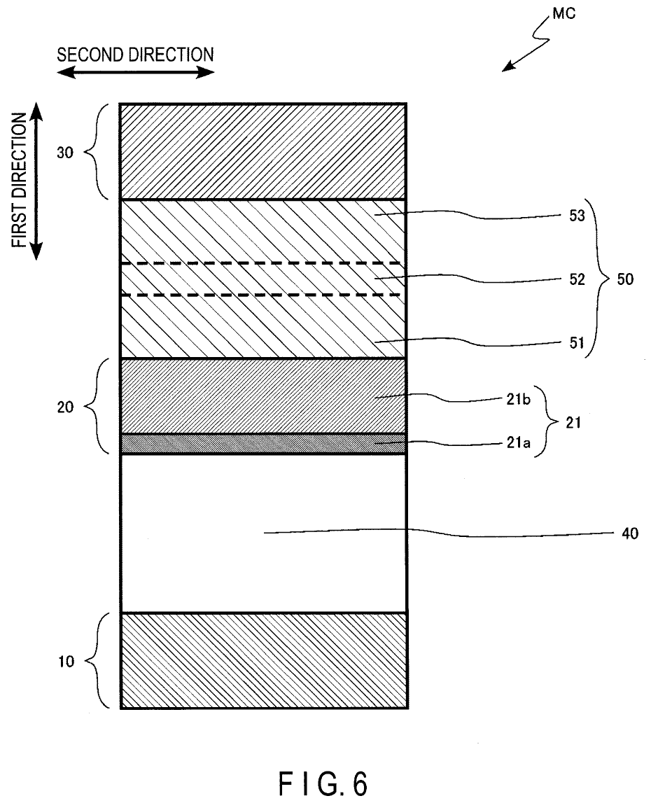

FIG. 6 is a schematic sectional view of a memory cell MC of the storage device in the first modification of the first embodiment. FIG. 6 is a diagram corresponding to FIG. 2 in the first embodiment.

In the memory cell MC of the storage device in the first modification of the first embodiment, the first electrode 10 includes no first carbon layer 11.

The first electrode 10 is made of metal, for example. The first electrode 10 contains, for example, at least one substance selected from a group consisting of carbon nitride, tungsten, tungsten carbide, tungsten nitride, titanium, titanium nitride, tantalum, tantalum carbide, and tantalum nitride.

According to the first modification of the first embodiment, similar to the first embodiment, the switching element where the interface between the second electrode 20 and the switching layer 40 is prevented from peeling can be achieved. Consequently, the storage device having excellent characteristics can be achieved.

### Second Modification

A storage device in a second modification of the first embodiment is different from the storage device in the first embodiment in that the carbon layer of the first electrode includes no first region.

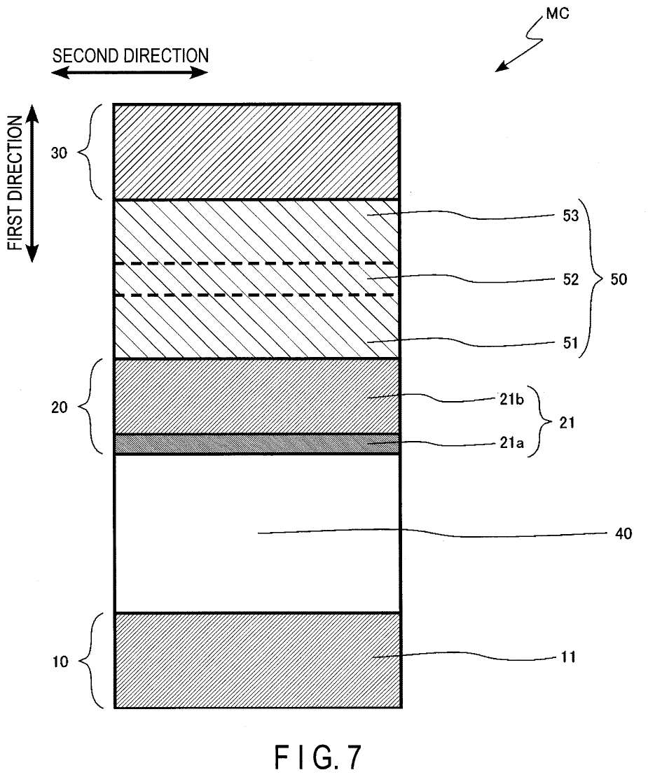

FIG. 7 is a schematic sectional view of a memory cell MC of the storage device in the second modification of the first embodiment. FIG. 7 is a diagram corresponding to FIG. 2 in the first embodiment.

In the memory cell MC of the storage device in the second modification of the first embodiment, the first carbon layer 11 of the first electrode 10 includes no first high-concentration region 11a. The first carbon layer 11 contains no fourth element, for example.

According to the second modification of the first embodiment, similar to the first embodiment, the switching element where the interface between the second electrode 20 and the switching layer 40 is prevented from peeling can be achieved. Consequently, the storage device having excellent characteristics can be achieved.

### Third Modification

A storage device in a third modification of the first embodiment is different from the storage device in the first embodiment in that the second electrode includes no carbon layer.

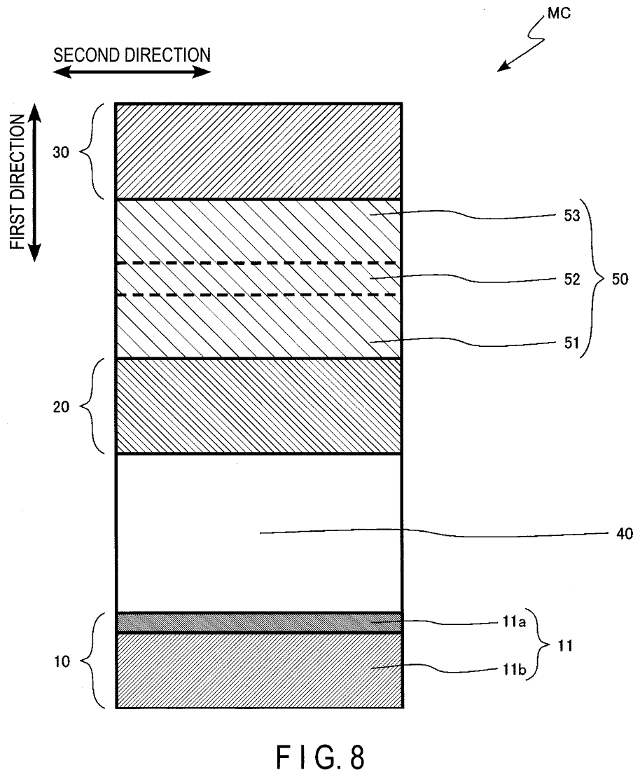

FIG. 8 is a schematic sectional view of a memory cell MC of the storage device in the third modification of the first embodiment. FIG. 8 is a diagram corresponding to FIG. 2 in the first embodiment.

In the memory cell MC of the storage device in the third modification of the first embodiment, the second electrode 20 includes no second carbon layer 21.

The second electrode 20 is made of metal, for example. The second electrode 20 contains, for example, at least one substance selected from a group consisting of carbon nitride, tungsten, tungsten carbide, tungsten nitride, titanium, titanium nitride, tantalum, tantalum carbide, and tantalum nitride.

According to the third modification of the first embodiment, similar to the first embodiment, the switching element where the interface between the first electrode 10 and the switching layer 40 is prevented from peeling can be realized. Consequently, the storage device having excellent characteristics can be realized.

### Fourth Modification

A storage device in a fourth modification of the first embodiment is different from the storage device in the first embodiment in that the carbon layer of the second electrode includes no first region.

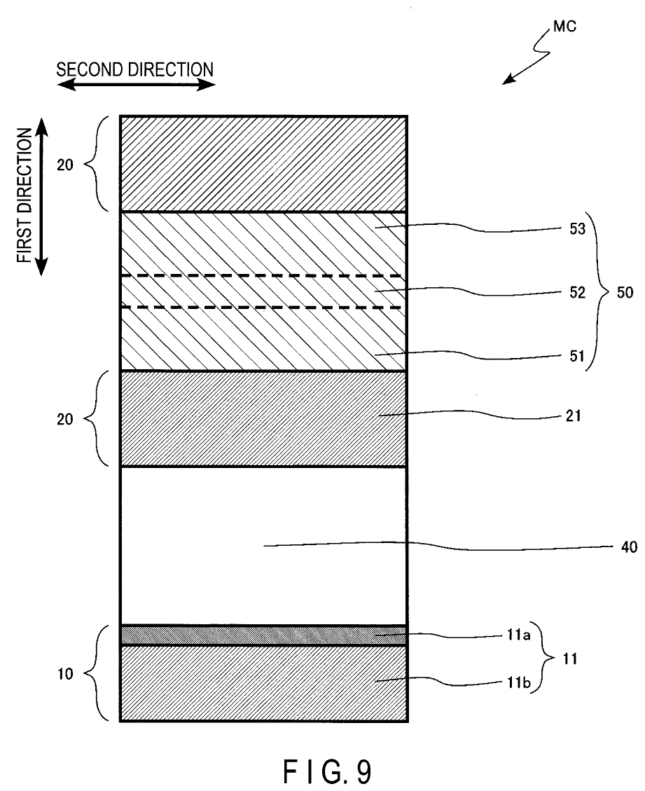

FIG. 9 is a schematic sectional view of a memory cell MC of the storage device in the fourth modification of the first embodiment. FIG. 9 is a diagram corresponding to FIG. 2 in the first embodiment.

In the memory cell MC of the storage device in the fourth modification of the first embodiment, the second carbon layer 21 of the second electrode 20 includes no second high-concentration region 21a. The second carbon layer 21 contains no fourth element, for example.

According to the fourth modification of the first embodiment, similar to the first embodiment, the switching element where the interface between the first electrode 10 and the switching layer 40 is prevented from peeling can be achieved. Consequently, the storage device having excellent characteristics can be achieved.

### Second Embodiment

A storage device in a second embodiment is different from the storage device in the first embodiment in that the carbon layer includes no second region. Hereinafter, the redundant description in the first embodiment may be omitted.

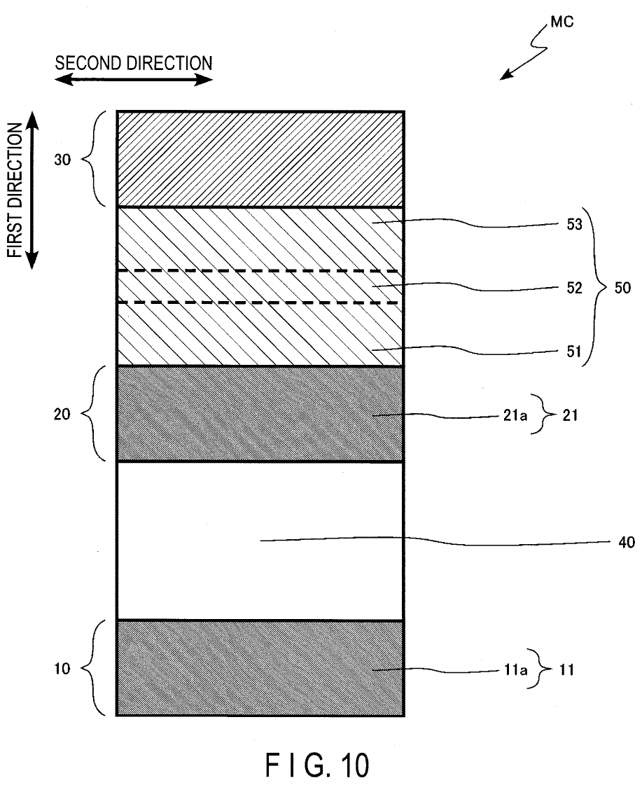

FIG. 10 is a schematic sectional view of the memory cell MC of the storage device in the second embodiment. FIG. 10 is a diagram corresponding to FIG. 2 in the first embodiment.

In the memory cell MC of the storage device in the second embodiment, the first carbon layer 11 of the first electrode 10 includes the first high-concentration region 11a but does not include the first low-concentration region 11b. In the memory cell MC of the storage device in the second embodiment, the second carbon layer 21 of the second electrode 20 includes the second high-concentration region 21a but does not include the second low-concentration region 21b.

According to the second embodiment, similar to the first embodiment, the switching element where the peeling on the interface between the first electrode 10 and the switching layer 40, and the peeling on the interface between the second electrode 20 and the switching layer 40 are prevented can be achieved. Consequently, the storage device having excellent characteristics can be achieved.

### Third Embodiment

A storage device in a third embodiment is different from the storage device in the first embodiment in that the carbon layer includes a metal layer. Hereinafter, the redundant description in the first embodiment may be omitted.

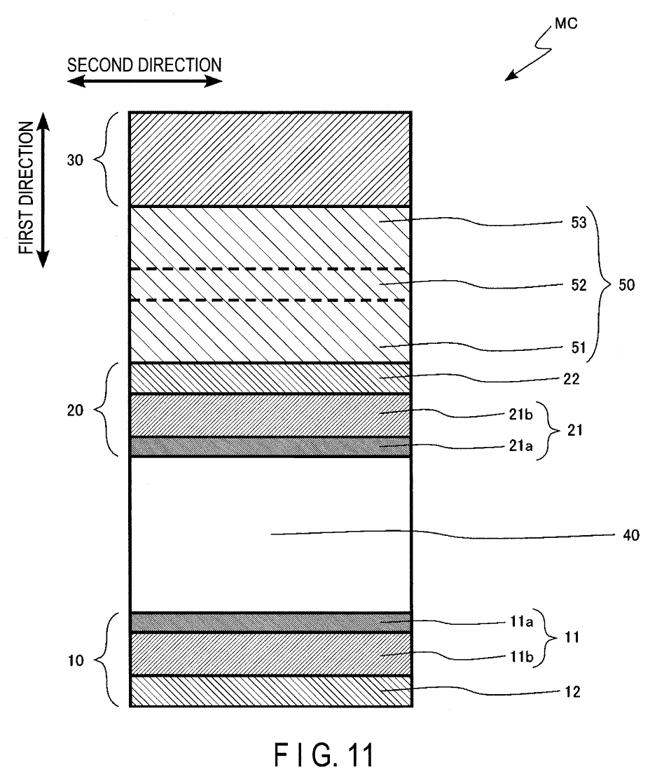

FIG. 11 is a schematic sectional view of the memory cell MC of the storage device in the third embodiment. FIG. 11 is a diagram corresponding to FIG. 2 in the first embodiment.

The first electrode 10 of the memory cell MC of the storage device in the third embodiment includes a first metal layer 12. The first carbon layer 11 is provided between the first metal layer 12 and the switching layer 40.

The first metal layer 12 is made of metal, for example. The first metal layer 12 contains, for example, at least one substance selected from a group consisting of carbon nitride, tungsten, tungsten carbide, tungsten nitride, titanium, titanium nitride, tantalum, tantalum carbide, and tantalum nitride.

The second electrode 20 of the memory cell MC of the storage device in the third embodiment includes a second metal layer 22. The second carbon layer 21 is provided between the second metal layer 22 and the switching layer 40.

The second metal layer 22 is made of metal, for example. The second metal layer 22 contains, for example, at least one substance selected from a group consisting of carbon nitride, tungsten, tungsten carbide, tungsten nitride, titanium, titanium nitride, tantalum, tantalum carbide, and tantalum nitride.

According to the third embodiment, similar to the first embodiment, the switching element where the peeling on the interface between the first electrode 10 and the switching layer 40, and the peeling on the interface between the second electrode 20 and the switching layer 40 are prevented can be achieved. Consequently, the storage device having excellent characteristics can be achieved.

### Fourth Embodiment

A storage device in a fourth embodiment is different from the storage device in the first embodiment in that the carbon layer includes a third region. Hereinafter, the redundant description in the first embodiment may be omitted.

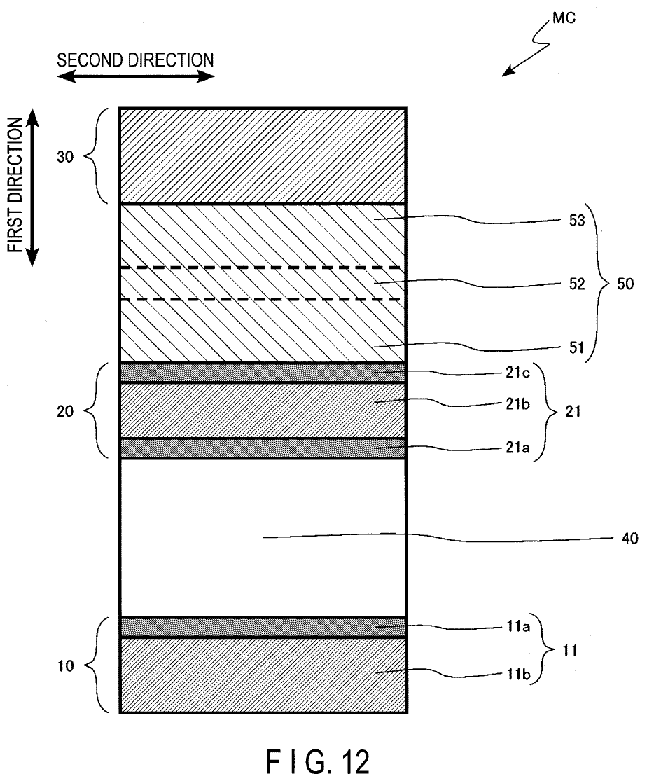

FIG. 12 is a schematic sectional view of the memory cell MC of the storage device in the fourth embodiment. FIG. 12 is a diagram corresponding to FIG. 2 in the first embodiment.

The second carbon layer 21 of the second electrode 20 of the memory cell MC of the storage device in the fourth embodiment includes a third high-concentration region 21c. The third high-concentration region 21c is also referred to as the third region.

The third high-concentration region 21c contains at least one fourth element selected from a group consisting of silicon (Si), aluminum (Al), phosphorus (P), gallium (Ga), and germanium (Ge).

The second low-concentration region 21b is provided between the second high-concentration region 21a and the third high-concentration region 21c. The atomic concentration of the fourth element in the third high-concentration region 21c is higher than the atomic concentration of the fourth element in the second low-concentration region 21b.

The ratio of the atomic concentration of the fourth element to the sum of the atomic concentration of carbon (C) and the atomic concentration of the fourth element in the third high-concentration region 21c ranges between, for example, 1% and 20%, inclusive.

According to the fourth embodiment, similar to the first embodiment, the switching element where the peeling on the interface between the first electrode 10 and the switching layer 40, and the peeling on the interface between the second electrode 20 and the switching layer 40 are prevented can be achieved. Consequently, the storage device having excellent characteristics can be achieved.

### Fifth Embodiment

A storage device in a fifth embodiment is different from the storage device in the first embodiment in that it is a resistive memory (ReRAM). Hereinafter, the redundant description in the first embodiment is partially omitted.

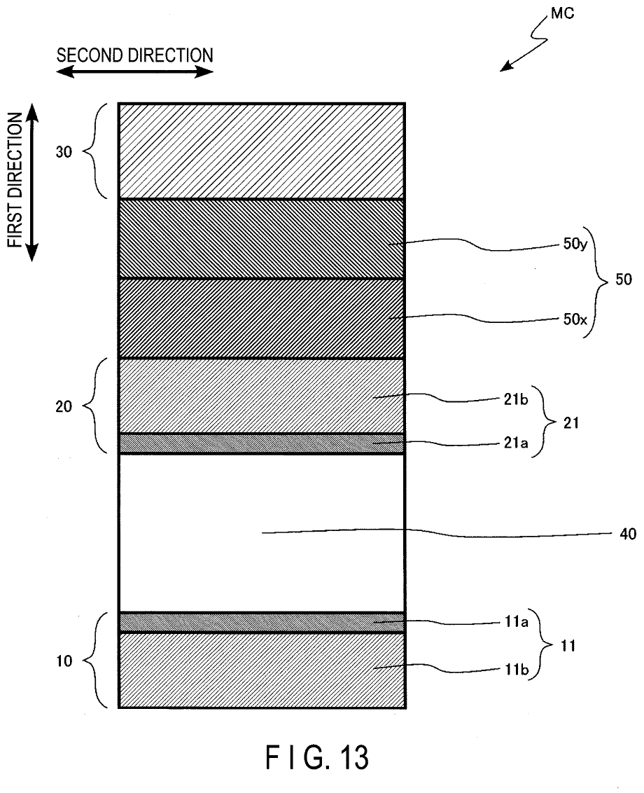

FIG. 13 is a schematic sectional view of the memory cell MC of the storage device in the fifth embodiment. FIG. 13 shows a section of one memory cell MC indicated by, for example, a broken-line circle in the memory cell array 100 in FIG. 1.

As shown in FIG. 13, the memory cell MC includes the first electrode 10, the second electrode 20, the third electrode 30, the switching layer 40, and the resistive layer 50. The first electrode 10 includes a first carbon layer 11. The second electrode 20 includes a second carbon layer 21. The first carbon layer 11 includes a first high-concentration region 11a and a first low-concentration region 11b. The second carbon layer 21 includes a second high-concentration region 21a and a second low-concentration region 21b.

The configuration of the switching layer 40 is similar to that in the storage device in the first embodiment.

The resistive layer 50 includes the high-resistance layer 50x, and the low-resistance layer 50y.

The high-resistance layer 50x is made of, for example, a metal oxide. The high-resistance layer 50x is made of, for example, aluminum oxide, hafnium oxide, zirconium oxide, tantalum oxide, or niobium oxide.

The low-resistance layer 50y is made of, for example, a metal oxide. The low-resistance layer 50y is made of, for example, titanium oxide, niobium oxide, tantalum oxide, or tungsten oxide.

The resistive layer 50 has a function of storing data by resistance change. The resistive layer 50 has, for example, characteristics in which the electrical resistance changes with application of a predetermined voltage.

By applying a voltage to the resistive layer 50, the resistive layer 50 changes from a high-resistance state to a low-resistance state, or from the low-resistance state to the high-resistance state. By applying the voltage to the resistive layer 50, oxygen ions move between the high-resistance layer 50x and the low-resistance layer 50y, and the amount of oxygen deficiency (or the amount of oxygen vacancy) in the low-resistance layer 50y changes. With the amount of oxygen deficiency in the low-resistance layer 50y, the conductivity of the resistive layer 50 changes. The low-resistance layer 50y is made of what is called a vacancy modulated conductive oxide.

For example, the high-resistance state is defined as data “1”, and the low-resistance state is defined as data “0”. The memory cell MC can store one-bit data of “0” and “1”.

According to the fifth embodiment, similar to the first embodiment, the switching element where the peeling on the interface between the first electrode 10 and the switching layer 40, and the peeling on the interface between the second electrode 20 and the switching layer 40 are prevented can be achieved. Consequently, the storage device having excellent characteristics can be achieved.

### Sixth Embodiment

A storage device in a sixth embodiment includes a memory cell that includes a first electrode, a second electrode, and a memory layer provided between the first electrode and the second electrode. The memory layer contains: an oxide, a nitride, or an oxynitride of at least one first element selected from a group consisting of aluminum (Al), silicon (Si), germanium (Ge), zirconium (Zr), yttrium (Y), tantalum (Ta), lanthanum (La), cerium (Ce), titanium (Ti), hafnium (Hf), and magnesium (Mg), at least one second element that is different from the first element and is selected from a group consisting of aluminum (Al), zinc (Zn), tin (Sn), gallium (Ga), bismuth (Bi), and indium (In), and at least one third element selected from a group consisting of tellurium (Te), sulfur (S), selenium (Se), and antimony (Sb). At least one electrode selected from the first electrode and the second electrode includes a carbon layer. The carbon layer includes a first region that is in contact with the memory layer, and contains at least one fourth element selected from a group consisting of silicon (Si), aluminum (Al), phosphorus (P), gallium (Ga), and germanium (Ge).

The storage device in the sixth embodiment further includes a plurality of first lines, and a plurality of second lines that intersect the plurality of first lines. The memory cell is provided in a region where one of the plurality of first lines intersects one of the plurality of second lines.

The storage device in the sixth embodiment is different from the storage device in the first embodiment in that the memory cell does not include the third electrode and the resistive layer, and has a configuration similar to that of the switching layer in the first embodiment as the memory layer. Hereinafter, the redundant description in the first embodiment is partially omitted.

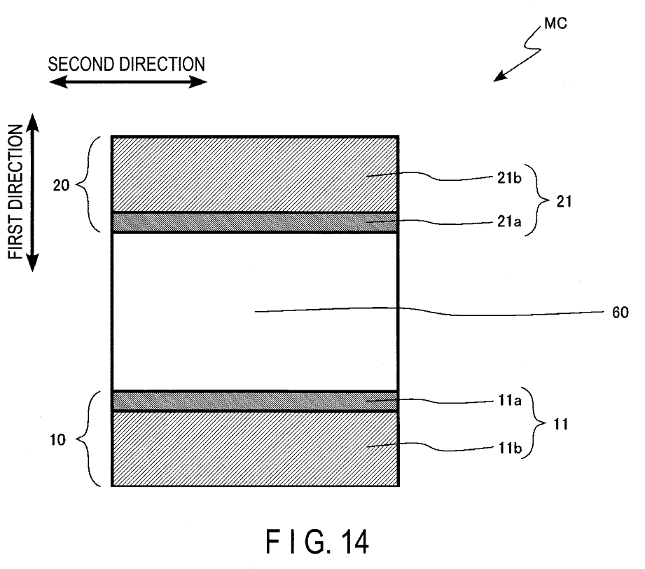

FIG. 14 is a schematic sectional view of the memory cell MC of the storage device in the sixth embodiment. FIG. 14 shows a section of one memory cell MC indicated by, for example, a broken-line circle in the memory cell array 100 in FIG. 1.

As shown in FIG. 14, the memory cell MC includes a first electrode 10, a second electrode 20, and a memory layer 60. The first electrode 10 includes a first carbon layer 11. The second electrode 20 includes a second carbon layer 21. The first carbon layer 11 includes a first high-concentration region 11a and a first low-concentration region 11b. The second carbon layer 21 includes a second high-concentration region 21a and a second low-concentration region 21b.

The first electrode 10, the memory layer 60, and the second electrode 20 constitute a memory element of the memory cell MC. The memory element of the memory cell MC has a switching function, and also has a function of storing information.

The memory layer 60 has a configuration similar to that of the switching layer 40 in the first embodiment.

The memory layer 60 is provided between the first electrode 10 and the second electrode 20. The memory layer 60 is in contact with, for example, the first electrode 10 and the second electrode 20.

The memory layer 60 has nonlinear current-voltage characteristics in which the current steeply rises at a specific threshold voltage. The memory layer 60 has characteristics in which the threshold voltage changes with application of a predetermined voltage. The memory layer 60 has characteristics in which the electrical resistance changes with application of a predetermined voltage. In the sixth embodiment, the high-resistance state is a state where the resistance of the memory layer 60 at a read voltage is relatively high. In the sixth embodiment, the low-resistance state is a state where the resistance of the memory layer 60 at the read voltage is relatively low.

The memory layer 60 has a function of preventing increase in semi-selected leakage current that flows through a semi-selected cell. The memory layer 60 has a function of storing data by resistance change. The memory layer 60 performs the function of the switching layer 40 and the function of the resistive layer 50 in the first embodiment with a single layer.

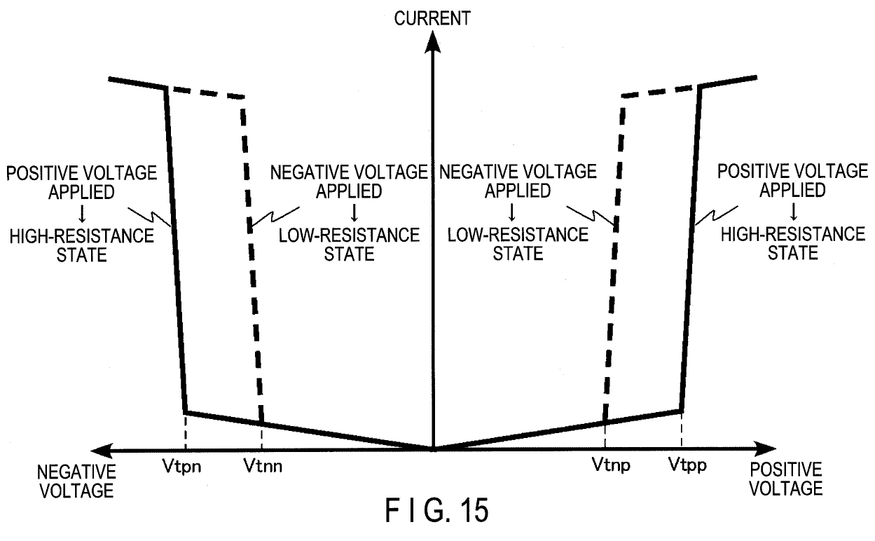

FIG. 15 is a diagram illustrating the current-voltage characteristics of the memory element in the sixth embodiment. The abscissa axis indicates the voltage applied to the memory element, and the ordinate axis indicates the current flowing through the memory element. FIG. 15 indicates, on the abscissa axis, the voltage applied to the second electrode 20 with reference to the potential of the first electrode 10. FIG. 15 shows the current-voltage characteristics of the memory layer 60 in the sixth embodiment. FIG. 15 shows the current-voltage characteristics of the memory cell MC in the sixth embodiment.

The memory element in the sixth embodiment exhibits different current-voltage characteristics between a case of applying a predetermined positive voltage to the second electrode 20 and a case of applying a predetermined negative voltage to the second electrode 20. FIG. 15 indicates the current-voltage characteristics in the case of applying the predetermined positive voltage to the second electrode 20 with solid lines, and indicates the current-voltage characteristics in the case of applying the predetermined negative voltage to the second electrode 20 with broken lines.

In the case of applying the predetermined positive voltage to the second electrode 20, the current steeply rises at the first positive voltage side threshold voltage Vtpp on the positive voltage side. In the case of applying the predetermined positive voltage to the second electrode 20, the current steeply rises at the first negative voltage side threshold voltage Vtpn on the negative voltage side.

On the other hand, in the case of applying the predetermined negative voltage to the second electrode 20, the current steeply rises at the second positive voltage side threshold voltage Vtnp on the positive voltage side. In the case of applying the predetermined negative voltage to the second electrode 20, the current steeply rises at the second negative voltage side threshold voltage Vtnn on the negative voltage side.

A first positive voltage side threshold voltage Vtpp is higher than a second positive voltage side threshold voltage Vtnp. A first negative voltage side threshold voltage Vtpn is lower than a second negative voltage side threshold voltage Vtnn.

The memory element in the sixth embodiment can be in each of the high-resistance state and the low-resistance state on each of the positive voltage side and the negative voltage side. In the case of applying the predetermined positive voltage to the second electrode 20, the state is the high-resistance state on each of the positive voltage side and the negative voltage side. On the other hand, in the case of applying the predetermined negative voltage to the second electrode 20, the state is the low-resistance state on each of the positive voltage side and the negative voltage side. Hereinafter, the high-resistance state is defined as data “1”, and the low-resistance state is defined as data “0”. The memory cell MC can store one-bit data of “0” and “1”.

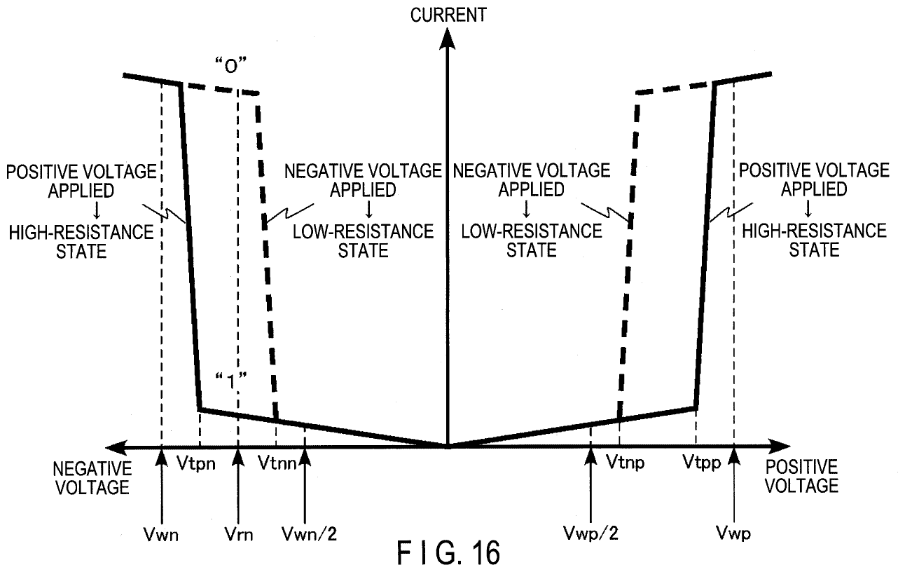

FIG. 16 is a diagram illustrating a first operation example of memory operation of the storage device in the sixth embodiment. FIG. 16 shows a positive-side write voltage Vwp, a half voltage of the positive-side write voltage Vwp (Vwp/2), a negative-side write voltage Vwn, a half voltage of the negative-side write voltage Vwn (Vwn/2), and a negative-side read voltage Vrn when the memory operation is performed.

In the first operation example, the high-resistance state and the low-resistance state on the negative voltage side are used for the memory operation. In the first operation example, the negative-side read voltage Vrn is used as a read voltage.

When data “1” is written into the selected cell, the positive-side write voltage Vwp is applied to the second electrode 20. The positive-side write voltage Vwp is a voltage higher than the first positive voltage side threshold voltage Vtpp. By applying the positive-side write voltage Vwp to the second electrode 20, the high-resistance state is achieved on the negative voltage side, and data “1” is written into the selected cell.

When data “0” is written into the selected cell, the negative-side write voltage Vwn is applied to the second electrode 20. The negative-side write voltage Vwn is a voltage lower than the first negative voltage side threshold voltage Vtpn. By applying the negative-side write voltage Vwn to the second electrode 20, the low-resistance state is achieved on the negative voltage side, and data “0” is written into the selected cell.

In the first operation example, in the case where data stored in the selected cell is data “0” when data “1” is written into the selected cell, the current flows as long as the positive-side write voltage Vwp is higher than the second positive voltage side threshold voltage Vtnp even if it is lower than the first positive voltage side threshold voltage Vtpp. Accordingly, there is a possibility that data “1” can be written. Consequently, for example, by setting the positive-side write voltage Vwp to a voltage between the second positive voltage side threshold voltage Vtnp and the first positive voltage side threshold voltage Vtpp, a low power consumption and high reliability of the storage device can be achieved.

Note that when the positive-side write voltage Vwp is applied to the selected cell, the voltage Vwp/2 is applied to the semi-selected cell. Note that when the negative-side write voltage Vwn is applied to the selected cell, the voltage Vwn/2 is applied to the semi-selected cell. The voltage Vwp/2 is lower than the second positive voltage side threshold voltage Vtnp. The voltage Vwn/2 is higher than the second negative voltage side threshold voltage Vtnn.

Consequently, even if the semi-selected cell is in the low-resistance state, the semi-selected leakage current flowing through the semi-selected cell can be prevented. Consequently, the memory element also functions as a switching element.

When the data in the selected cell is read, the negative-side read voltage Vrn is applied to the selected cell. By detecting change in current or change in potential caused by the difference in flowing current between the case of data “1” and the case of data “0”, the data in the selected cell can be determined.

Note that in the case of the first operation example, irrespective of whether the data in the selected cell is data “1” or data “0”, data destruction due to application of the negative-side read voltage Vrn does not occur. In other words, in the case of the first operation example, irrespective of whether the data in the selected cell is data “1” or data “0”, nondestructive read can be performed.

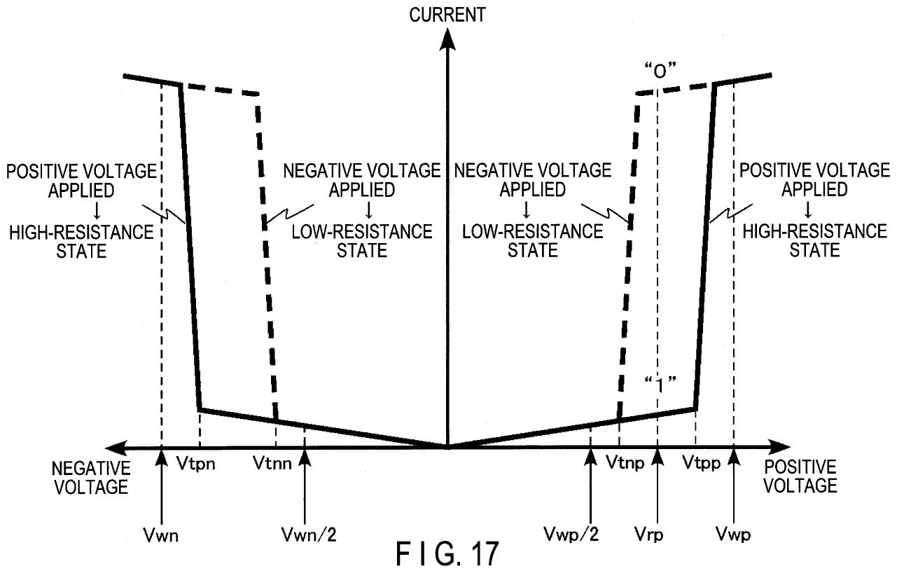

FIG. 17 is a diagram illustrating a second operation example of memory operation of the storage device in the sixth embodiment. FIG. 17 shows a positive-side write voltage Vwp, a half voltage of the positive-side write voltage Vwp (Vwp/2), a negative-side write voltage Vwn, a half voltage of the negative-side write voltage Vwn (Vwn/2), and a positive-side read voltage Vrp when the memory operation is performed.

In the second operation example, the high-resistance state and the low-resistance state on the positive voltage side are used for the memory operation. In the second operation example, the positive-side read voltage Vrp is used as a read voltage.

When data “1” is written into the selected cell, the positive-side write voltage Vwp is applied to the second electrode 20. The positive-side write voltage Vwp is a voltage higher than the first positive voltage side threshold voltage Vtpp. By applying the positive-side write voltage Vwp to the second electrode 20, the high-resistance state is achieved on the positive voltage side, and data “1” is written into the selected cell.

When data “0” is written into the selected cell, the negative-side write voltage Vwn is applied to the second electrode 20. The negative-side write voltage Vwn is a voltage lower than the first negative voltage side threshold voltage Vtpn. By applying the negative-side write voltage Vwn to the second electrode 20, the low-resistance state is achieved on the positive voltage side, and data “0” is written into the selected cell.

In the second operation example, in the case where data stored in the selected cell is data “0” when data “1” is written into the selected cell, the current flows as long as the positive-side write voltage Vwp is higher than the second positive voltage side threshold voltage Vtnp even if it is lower than the first positive voltage side threshold voltage Vtpp. Accordingly, there is a possibility that data “1” can be written. Consequently, for example, by setting the positive-side write voltage Vwp to a voltage between the second positive voltage side threshold voltage Vtnp and the first positive voltage side threshold voltage Vtpp, a low power consumption and high reliability of the storage device can be achieved.

Note that when the positive-side write voltage Vwp is applied to the selected cell, the voltage Vwp/2 is applied to the semi-selected cell. Note that when the negative-side write voltage Vwn is applied to the selected cell, the voltage Vwn/2 is applied to the semi-selected cell. The voltage Vwp/2 is lower than the second positive voltage side threshold voltage Vtnp. The voltage Vwn/2 is higher than the second negative voltage side threshold voltage Vtnn.

Consequently, even if the semi-selected cell is in the low-resistance state, the semi-selected leakage current flowing through the semi-selected cell can be prevented. Consequently, the memory element also functions as a switching element.

When the data in the selected cell is read, the positive-side read voltage Vrp is applied to the selected cell. By detecting change in current or change in potential caused by the difference in flowing current between the case of data “1” and the case of data “0”, the data in the selected cell can be determined.

Note that in the case of the second operation example, when the data in the selected cell is data “1”, data destruction due to application of the positive-side read voltage Vrp does not occur. In other words, in the case of the second operation example, when the data in the selected cell is data “1”, nondestructive read can be performed.

On the other hand, when the data in the selected cell is data “0”, there is a possibility that by applying the positive-side read voltage Vrp higher than the second positive voltage side threshold voltage Vtnp, current flows, and the data in the selected cell changes to data “1”. In other words, in the case of the second operation example, when the data in the selected cell is data “0”, destructive read possibly occurs. Consequently, when the data in the selected cell is data “0”, there is a possibility that rewriting of data “0” is required to maintain the data in the selected cell after data is read from the selected cell.

### First Modification

A storage device in a first modification of the sixth embodiment is different from the storage device in the sixth embodiment in that the current-voltage characteristics of the memory element are different.

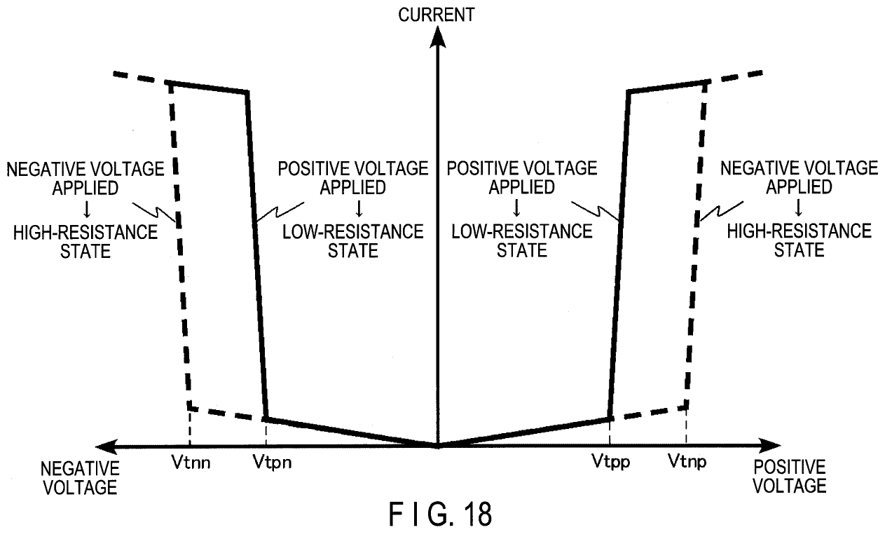

FIG. 18 is a diagram illustrating the current-voltage characteristics of the memory element in the first modification of the sixth embodiment. The abscissa axis indicates the voltage applied to the memory element, and the ordinate axis indicates the current flowing through the memory element. FIG. 18 indicates, on the abscissa axis, the voltage applied to the second electrode 20 with reference to the potential of the first electrode 10. FIG. 18 shows the current-voltage characteristics of the memory layer 60 in the first modification of the sixth embodiment. FIG. 18 shows the current-voltage characteristics of the memory cell MC in the first modification of the sixth embodiment.

The memory element in the first modification of the sixth embodiment exhibits different current-voltage characteristics between a case of applying a predetermined positive voltage to the second electrode 20 and a case of applying a predetermined negative voltage to the second electrode 20. FIG. 18 indicates the current-voltage characteristics in the case of applying the predetermined positive voltage to the second electrode 20 with solid lines, and indicates the current-voltage characteristics in the case of applying the predetermined negative voltage to the second electrode 20 with broken lines.

In the case of applying the predetermined positive voltage to the second electrode 20, the current steeply rises at the first positive voltage side threshold voltage Vtpp on the positive voltage side. In the case of applying the predetermined positive voltage to the second electrode 20, the current steeply rises at the first negative voltage side threshold voltage Vtpn on the negative voltage side.

On the other hand, in the case of applying the predetermined negative voltage to the second electrode 20, the current steeply rises at the second positive voltage side threshold voltage Vtnp on the positive voltage side. In the case of applying the predetermined negative voltage to the second electrode 20, the current steeply rises at the second negative voltage side threshold voltage Vtnn on the negative voltage side.

A first positive voltage side threshold voltage Vtpp is lower than a second positive voltage side threshold voltage Vtnp. A first negative voltage side threshold voltage Vtpn is higher than a second negative voltage side threshold voltage Vtnn.

The memory element in the first modification of the sixth embodiment can be in each of the high-resistance state and the low-resistance state on each of the positive voltage side and the negative voltage side. In the case of applying the predetermined positive voltage to the second electrode 20, the state is the low-resistance state on each of the positive voltage side and the negative voltage side. On the other hand, in the case of applying the predetermined negative voltage to the second electrode 20, the state is the high-resistance state on each of the positive voltage side and the negative voltage side. Hereinafter, the high-resistance state is defined as data “1”, and the low-resistance state is defined as data “0”. The memory cell MC can store one-bit data of “0” and “1”.

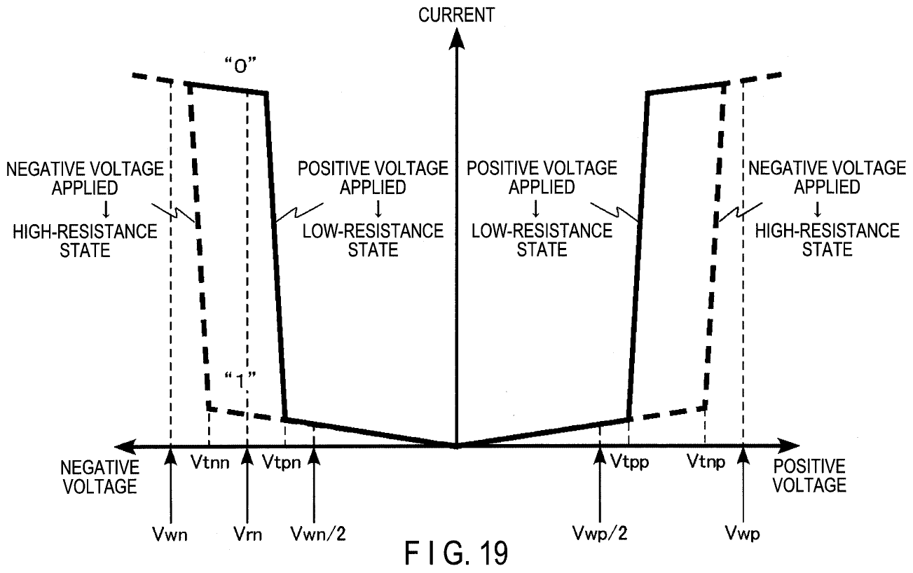

FIG. 19 is a diagram illustrating a third operation example of memory operation of the storage device in the first modification of the sixth embodiment. FIG. 19 shows a positive-side write voltage Vwp, a half voltage of the positive-side write voltage Vwp (Vwp/2), a negative-side write voltage Vwn, a half voltage of the negative-side write voltage Vwn (Vwn/2), and a negative-side read voltage Vrn when the memory operation is performed.

In the third operation example, the high-resistance state and the low-resistance state on the negative voltage side are used for the memory operation. In the third operation example, the negative-side read voltage Vrn is used as a read voltage.

When data “1” is written into the selected cell, the negative-side write voltage Vwn is applied to the second electrode 20. The negative-side write voltage Vwn is a voltage lower than the second negative voltage side threshold voltage Vtnn. By applying the negative-side write voltage Vwn to the second electrode 20, the high-resistance state is achieved on the negative voltage side, and data “1” is written into the selected cell.

When data “0” is written into the selected cell, the positive-side write voltage Vwp is applied to the second electrode 20. The positive-side write voltage Vwp is a voltage higher than the second positive voltage side threshold voltage Vtnp. By applying the positive-side write voltage Vwp to the second electrode 20, the low-resistance state is achieved on the negative voltage side, and data “0” is written into the selected cell.

In the third operation example, in the case where data stored in the selected cell is data “0” when data “1” is written into the selected cell, the current flows as long as the negative-side write voltage Vwn is lower than the first negative voltage side threshold voltage Vtpn even if it is higher than the second negative voltage side threshold voltage Vtnn. Accordingly, there is a possibility that data “1” can be written. Consequently, for example, by setting the negative-side write voltage Vwn to a voltage between the second negative voltage side threshold voltage Vtnn and the first negative voltage side threshold voltage Vtpn, a low power consumption and high reliability of the storage device can be achieved.

Note that when the positive-side write voltage Vwp is applied to the selected cell, the voltage Vwp/2 is applied to the semi-selected cell. Note that when the negative-side write voltage Vwn is applied to the selected cell, the voltage Vwn/2 is applied to the semi-selected cell. The voltage Vwp/2 is lower than the first positive voltage side threshold voltage Vtpp. The voltage Vwn/2 is higher than the first negative voltage side threshold voltage Vtpn.

Consequently, even if the semi-selected cell is in the low-resistance state, the semi-selected leakage current flowing through the semi-selected cell can be prevented. Consequently, the memory element also functions as a switching element.

When the data in the selected cell is read, the negative-side read voltage Vrn is applied to the selected cell. By detecting change in current or change in potential caused by the difference in flowing current between the case of data “1” and the case of data “0”, the data in the selected cell can be determined.

Note that in the case of the third operation example, when the data in the selected cell is data “1”, data destruction due to application of the negative-side read voltage Vrn does not occur. In other words, in the case of the third operation example, when the data in the selected cell is data “1”, nondestructive read can be performed.

On the other hand, when the data in the selected cell is data “0”, there is a possibility that by applying the negative-side read voltage Vrn lower than the first negative voltage side threshold voltage Vtpn, current flows, and the data in the selected cell changes to data “1”. In other words, in the case of the third operation example, when the data in the selected cell is data “0”, destructive read possibly occurs. Consequently, when the data in the selected cell is data “0”, there is a possibility that rewriting of data “0” is required to maintain the data in the selected cell after data is read from the selected cell.

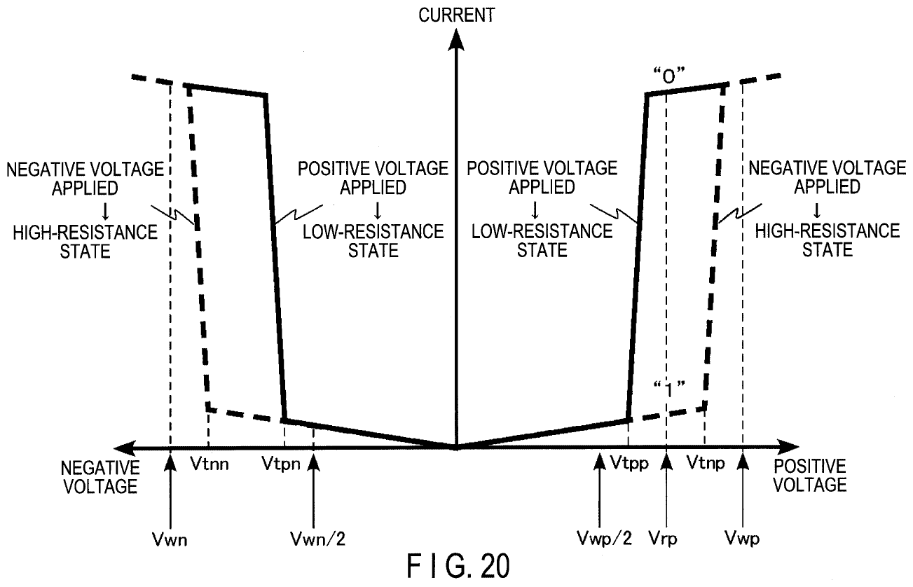

FIG. 20 is a diagram illustrating a fourth operation example of memory operation of the storage device in the first modification of the sixth embodiment. FIG. 20 shows a positive-side write voltage Vwp, a half voltage of the positive-side write voltage Vwp (Vwp/2), a negative-side write voltage Vwn, a half voltage of the negative-side write voltage Vwn (Vwn/2), and a positive-side read voltage Vrp when the memory operation is performed.

In the fourth operation example, the high-resistance state and the low-resistance state on the positive voltage side are used for the memory operation. In the fourth operation example, the positive-side read voltage Vrp is used as a read voltage.

When data “1” is written into the selected cell, the negative-side write voltage Vwn is applied to the second electrode 20. The negative-side write voltage Vwn is a voltage lower than the second negative voltage side threshold voltage Vtnn. By applying the negative-side write voltage Vwn to the second electrode 20, the high-resistance state is achieved on the positive voltage side, and data “1” is written into the selected cell.

When data “0” is written into the selected cell, the positive-side write voltage Vwp is applied to the second electrode 20. The positive-side write voltage Vwp is a voltage higher than the second positive voltage side threshold voltage Vtnp. By applying the positive-side write voltage Vwp to the second electrode 20, the low-resistance state is achieved on the positive voltage side, and data “0” is written into the selected cell.

In the fourth operation example, in the case where data stored in the selected cell is data “0” when data “1” is written into the selected cell, the current flows as long as the negative-side write voltage Vwn is lower than the first negative voltage side threshold voltage Vtpn even if it is higher than the second negative voltage side threshold voltage Vtnn. Accordingly, there is a possibility that data “1” can be written. Consequently, for example, by setting the negative-side write voltage Vwn to a voltage between the second negative voltage side threshold voltage Vtnn and the first negative voltage side threshold voltage Vtpn, a low power consumption and high reliability of the storage device can be achieved.

Note that when the positive-side write voltage Vwp is applied to the selected cell, the voltage Vwp/2 is applied to the semi-selected cell. Note that when the negative-side write voltage Vwn is applied to the selected cell, the voltage Vwn/2 is applied to the semi-selected cell. The voltage Vwp/2 is lower than the first positive voltage side threshold voltage Vtpp. The voltage Vwn/2 is higher than the first negative voltage side threshold voltage Vtpn.

Consequently, even if the semi-selected cell is in the low-resistance state, the semi-selected leakage current flowing through the semi-selected cell can be prevented. Consequently, the memory element also functions as a switching element.

When the data in the selected cell is read, the positive-side read voltage Vrp is applied to the selected cell. By detecting change in current or change in potential caused by the difference in flowing current between the case of data “1” and the case of data “0”, the data in the selected cell can be determined.

Note that in the case of the fourth operation example, irrespective of whether the data in the selected cell is data “1” or data “0”, data destruction due to application of the positive-side read voltage Vrp does not occur. In other words, in the case of the fourth operation example, irrespective of whether the data in the selected cell is data “1” or data “0”, nondestructive read can be performed.

### Second Modification

A storage device in a second modification of the sixth embodiment is different from the storage device in the sixth embodiment in that the current-voltage characteristics of the memory element are different.

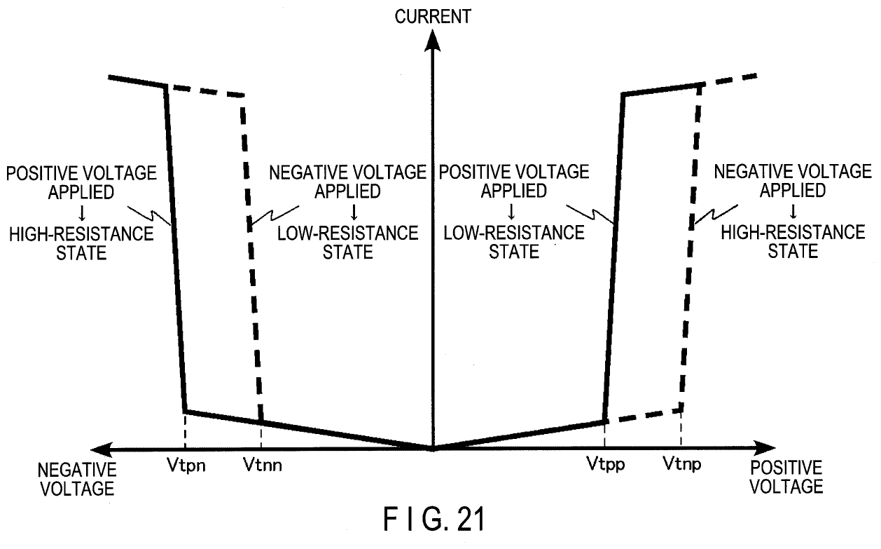

FIG. 21 is a diagram illustrating the current-voltage characteristics of the memory element in the second modification of the sixth embodiment. The abscissa axis indicates the voltage applied to the memory element, and the ordinate axis indicates the current flowing through the memory element. FIG. 21 indicates, on the abscissa axis, the voltage applied to the second electrode 20 with reference to the potential of the first electrode 10. FIG. 21 shows the current-voltage characteristics of the memory layer 60 in the second modification of the sixth embodiment. FIG. 21 shows the current-voltage characteristics of the memory cell MC in the second modification of the sixth embodiment.

The memory element in the second modification of the sixth embodiment exhibits different current-voltage characteristics between a case of applying a predetermined positive voltage to the second electrode 20 and a case of applying a predetermined negative voltage to the second electrode 20. FIG. 21 indicates the current-voltage characteristics in the case of applying the predetermined positive voltage to the second electrode 20 with solid lines, and indicates the current-voltage characteristics in the case of applying the predetermined negative voltage to the second electrode 20 with broken lines.

In the case of applying the predetermined positive voltage to the second electrode 20, the current steeply rises at the first positive voltage side threshold voltage Vtpp on the positive voltage side. In the case of applying the predetermined positive voltage to the second electrode 20, the current steeply rises at the first negative voltage side threshold voltage Vtpn on the negative voltage side.

On the other hand, in the case of applying the predetermined negative voltage to the second electrode 20, the current steeply rises at the second positive voltage side threshold voltage Vtnp on the positive voltage side. In the case of applying the predetermined negative voltage to the second electrode 20, the current steeply rises at the second negative voltage side threshold voltage Vtnn on the negative voltage side.

The first positive voltage side threshold voltage Vtpp is lower than the second positive voltage side threshold voltage Vtnp. The first negative voltage side threshold voltage Vtpn is lower than the second negative voltage side threshold voltage Vtnn.

The memory element in the second modification of the sixth embodiment can be in each of the high-resistance state and the low-resistance state on each of the positive voltage side and the negative voltage side. In the case of applying the predetermined positive voltage to the second electrode 20, the state is the low-resistance state on the positive voltage side, and the high-resistance state on the negative voltage side. On the other hand, in the case of applying the predetermined negative voltage to the second electrode 20, the state is the high-resistance state on the positive voltage side, and the low-resistance state on the negative voltage side. Hereinafter, the high-resistance state is defined as data “1”, and the low-resistance state is defined as data “0”. The memory cell MC can store one-bit data of “0” and “1”.

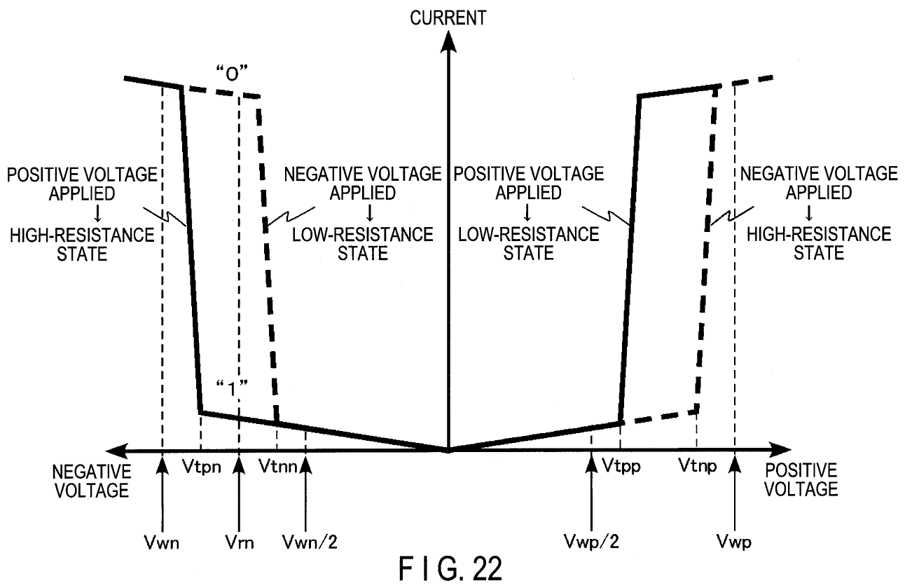

FIG. 22 is a diagram illustrating a fifth operation example of memory operation of the storage device in the second modification of the sixth embodiment. FIG. 22 shows a positive-side write voltage Vwp, a half voltage of the positive-side write voltage Vwp (Vwp/2), a negative-side write voltage Vwn, a half voltage of the negative-side write voltage Vwn (Vwn/2), and a negative-side read voltage Vrn when the memory operation is performed.

In the fifth operation example, the high-resistance state and the low-resistance state on the negative voltage side are used for the memory operation. In the fifth operation example, the negative-side read voltage Vrn is used as a read voltage.

When data “1” is written into the selected cell, the positive-side write voltage Vwp is applied to the second electrode 20. The positive-side write voltage Vwp is a voltage higher than the second positive voltage side threshold voltage Vtnp. By applying the positive-side write voltage Vwp to the second electrode 20, the high-resistance state is achieved on the negative voltage side, and data “1” is written into the selected cell.

When data “0” is written into the selected cell, the negative-side write voltage Vwn is applied to the second electrode 20. The negative-side write voltage Vwn is a voltage lower than the first negative voltage side threshold voltage Vtpn. By applying the negative-side write voltage Vwn to the second electrode 20, the low-resistance state is achieved on the negative voltage side, and data “0” is written into the selected cell.

Note that when the positive-side write voltage Vwp is applied to the selected cell, the voltage Vwp/2 is applied to the semi-selected cell. Note that when the negative-side write voltage Vwn is applied to the selected cell, the voltage Vwn/2 is applied to the semi-selected cell. The voltage Vwp/2 is lower than the first positive voltage side threshold voltage Vtpp. The voltage Vwn/2 is higher than the second negative voltage side threshold voltage Vtnn.

Consequently, even if the semi-selected cell is in the low-resistance state, the semi-selected leakage current flowing through the semi-selected cell can be prevented. Consequently, the memory element also functions as a switching element.

When the data in the selected cell is read, the negative-side read voltage Vrn is applied to the selected cell. By detecting change in current or change in potential caused by the difference in flowing current between the case of data “1” and the case of data “0”, the data in the selected cell can be determined.

Note that in the case of the fifth operation example, irrespective of whether the data in the selected cell is data “1” or data “0”, data destruction due to application of the negative-side read voltage Vrn does not occur. In other words, in the case of the fifth operation example, irrespective of whether the data in the selected cell is data “1” or data “0”, nondestructive read can be performed.

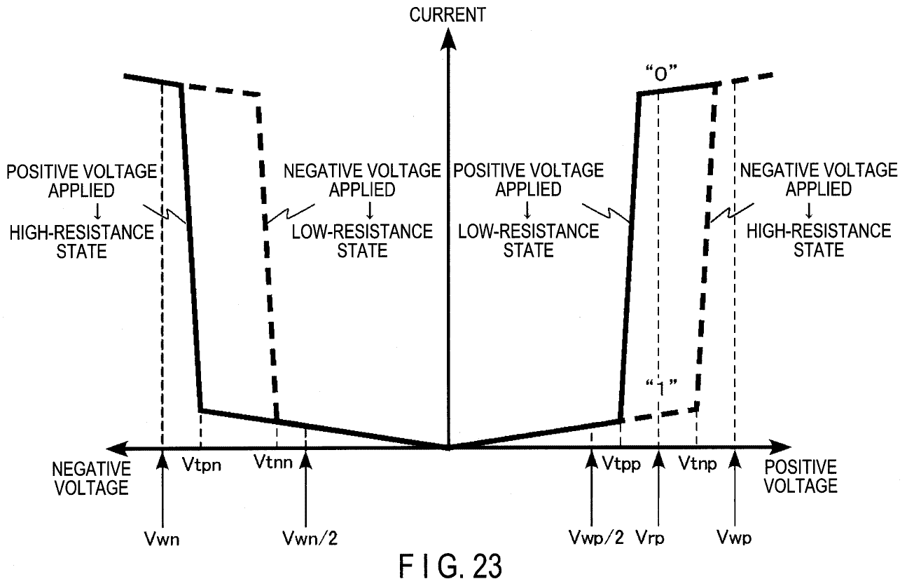

FIG. 23 is a diagram illustrating a sixth operation example of memory operation of the storage device in the second modification of the sixth embodiment. FIG. 23 shows a positive-side write voltage Vwp, a half voltage of the positive-side write voltage Vwp (Vwp/2), a negative-side write voltage Vwn, a half voltage of the negative-side write voltage Vwn (Vwn/2), and a positive-side read voltage Vrp when the memory operation is performed.

In the sixth operation example, the high-resistance state and the low-resistance state on the positive voltage side are used for the memory operation. In the sixth operation example, the positive-side read voltage Vrp is used as a read voltage.

When data “1” is written into the selected cell, the negative-side write voltage Vwn is applied to the second electrode 20. The negative-side write voltage Vwn is a voltage lower than the first negative voltage side threshold voltage Vtpn. By applying the negative-side write voltage Vwn to the second electrode 20, the high-resistance state is achieved on the positive voltage side, and data “1” is written into the selected cell.

When data “0” is written into the selected cell, the positive-side write voltage Vwp is applied to the second electrode 20. The positive-side write voltage Vwp is a voltage higher than the second positive voltage side threshold voltage Vtnp. By applying the positive-side write voltage Vwp to the second electrode 20, the low-resistance state is achieved on the positive voltage side, and data “0” is written into the selected cell.

Note that when the positive-side write voltage Vwp is applied to the selected cell, the voltage Vwp/2 is applied to the semi-selected cell. Note that when the negative-side write voltage Vwn is applied to the selected cell, the voltage Vwn/2 is applied to the semi-selected cell. The voltage Vwp/2 is lower than the first positive voltage side threshold voltage Vtpp. The voltage Vwn/2 is higher than the second negative voltage side threshold voltage Vtnn.

Consequently, even if the semi-selected cell is in the low-resistance state, the semi-selected leakage current flowing through the semi-selected cell can be prevented. Consequently, the memory element also functions as a switching element.

When the data in the selected cell is read, the positive-side read voltage Vrp is applied to the selected cell. By detecting change in current or change in potential caused by the difference in flowing current between the case of data “1” and the case of data “0”, the data in the selected cell can be determined.

Note that in the case of the sixth operation example, irrespective of whether the data in the selected cell is data “1” or data “0”, data destruction due to application of the positive-side read voltage Vrp does not occur. In other words, in the case of the sixth operation example, irrespective of whether the data in the selected cell is data “1” or data “0”, nondestructive read can be performed.

### Third Modification

A storage device in a third modification of the sixth embodiment is different from the storage device in the sixth embodiment in that the current-voltage characteristics of the memory element are different.

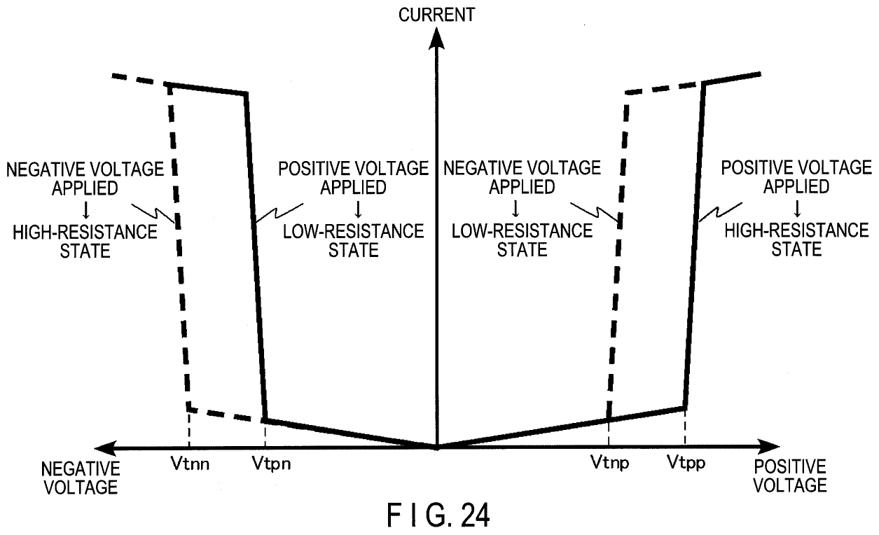

FIG. 24 is a diagram illustrating the current-voltage characteristics of the memory element in the third modification of the sixth embodiment. The abscissa axis indicates the voltage applied to the memory element, and the ordinate axis indicates the current flowing through the memory element. FIG. 24 indicates, on the abscissa axis, the voltage applied to the second electrode 20 with reference to the potential of the first electrode 10. FIG. 24 is a diagram illustrating the current-voltage characteristics of the memory layer 60 in the third modification of the sixth embodiment. FIG. 24 is a diagram illustrating the current-voltage characteristics of the memory cell MC in the third modification of the sixth embodiment.

The memory element in the third modification of the sixth embodiment exhibits different current-voltage characteristics between a case of applying a predetermined positive voltage to the second electrode 20 and a case of applying a predetermined negative voltage to the second electrode 20. FIG. 24 indicates the current-voltage characteristics in the case of applying the predetermined positive voltage to the second electrode 20 with solid lines, and indicates the current-voltage characteristics in the case of applying the predetermined negative voltage to the second electrode 20 with broken lines.

In the case of applying the predetermined positive voltage to the second electrode 20, the current steeply rises at the first positive voltage side threshold voltage Vtpp on the positive voltage side. In the case of applying the predetermined positive voltage to the second electrode 20, the current steeply rises at the first negative voltage side threshold voltage Vtpn on the negative voltage side.

On the other hand, in the case of applying the predetermined negative voltage to the second electrode 20, the current steeply rises at the second positive voltage side threshold voltage Vtnp on the positive voltage side. In the case of applying the predetermined negative voltage to the second electrode 20, the current steeply rises at the second negative voltage side threshold voltage Vtnn on the negative voltage side.

The first positive voltage side threshold voltage Vtpp is higher than the second positive voltage side threshold voltage Vtnp. The first negative voltage side threshold voltage Vtpn is higher than the second negative voltage side threshold voltage Vtnn.

The memory element in the third modification of the sixth embodiment can be in each of the high-resistance state and the low-resistance state on each of the positive voltage side and the negative voltage side. In the case of applying the predetermined positive voltage to the second electrode 20, the state is the high-resistance state on the positive voltage side, and the low-resistance state on the negative voltage side. On the other hand, in the case of applying the predetermined negative voltage to the second electrode 20, the state is the low-resistance state on the positive voltage side, and the high-resistance state on the negative voltage side. Hereinafter, the high-resistance state is defined as data “1”, and the low-resistance state is defined as data “0”. The memory cell MC can store one-bit data of “0” and “1”.

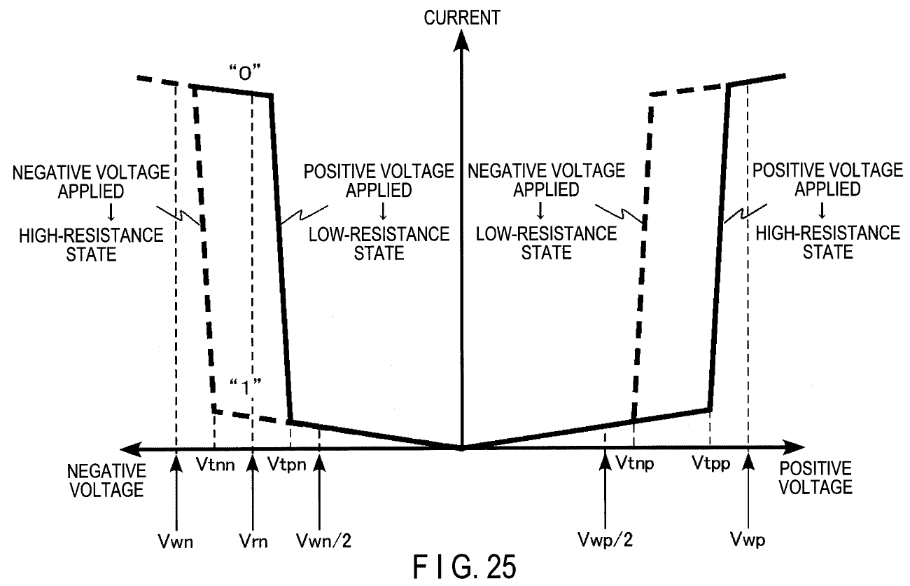

FIG. 25 is a diagram illustrating a seventh operation example of memory operation of the storage device in the third modification of the sixth embodiment. FIG. 25 shows a positive-side write voltage Vwp, a half voltage of the positive-side write voltage Vwp (Vwp/2), a negative-side write voltage Vwn, a half voltage of the negative-side write voltage Vwn (Vwn/2), and a negative-side read voltage Vrn when the memory operation is performed.

In the seventh operation example, the high-resistance state and the low-resistance state on the negative voltage side are used for the memory operation. In the seventh operation example, the negative-side read voltage Vrn is used as a read voltage.

When data “1” is written into the selected cell, the negative-side write voltage Vwn is applied to the second electrode 20. The negative-side write voltage Vwn is a voltage lower than the second negative voltage side threshold voltage Vtnn. By applying the negative-side write voltage Vwn to the second electrode 20, the high-resistance state is achieved on the negative voltage side, and data “1” is written into the selected cell.

When data “0” is written into the selected cell, the positive-side write voltage Vwp is applied to the second electrode 20. The positive-side write voltage Vwp is a voltage higher than the first positive voltage side threshold voltage Vtpp. By applying the positive-side write voltage Vwp to the second electrode 20, the low-resistance state is achieved on the negative voltage side, and data “0” is written into the selected cell.

In the seventh operation example, in the case where data stored in the selected cell is data “0” when data “1” is written into the selected cell, the current flows as long as the negative-side write voltage Vwn is lower than the first negative voltage side threshold voltage Vtpn even if it is higher than the second negative voltage side threshold voltage Vtnn. Accordingly, there is a possibility that data “1” can be written. Consequently, for example, by setting the negative-side write voltage Vwn to a voltage between the second negative voltage side threshold voltage Vtnn and the first negative voltage side threshold voltage Vtpn, a low power consumption and high reliability of the storage device can be achieved.

In the seventh operation example, in the case where data stored in the selected cell is data “1” when data “0” is written into the selected cell, the current flows as long as the positive-side write voltage Vwp is higher than the second positive voltage side threshold voltage Vtnp even if it is lower than the first positive voltage side threshold voltage Vtpp. Accordingly, there is a possibility that data “0” can be written. Consequently, for example, by setting the positive-side write voltage Vwp to a voltage between the second positive voltage side threshold voltage Vtnp and the first positive voltage side threshold voltage Vtpp, a low power consumption and high reliability of the storage device can be achieved.

Note that when the positive-side write voltage Vwp is applied to the selected cell, the voltage Vwp/2 is applied to the semi-selected cell. Note that when the negative-side write voltage Vwn is applied to the selected cell, the voltage Vwn/2 is applied to the semi-selected cell. The voltage Vwp/2 is lower than the second positive voltage side threshold voltage Vtnp. The voltage Vwn/2 is higher than the first negative voltage side threshold voltage Vtpn.

Consequently, even if the semi-selected cell is in the low-resistance state, the semi-selected leakage current flowing through the semi-selected cell can be prevented. Consequently, the memory element also functions as a switching element.

When the data in the selected cell is read, the negative-side read voltage Vrn is applied to the selected cell. By detecting change in current or change in potential caused by the difference in flowing current between the case of data “1” and the case of data “0”, the data in the selected cell can be determined.

Note that in the case of the seventh operation example, when the data in the selected cell is data “1”, data destruction due to application of the negative-side read voltage Vrn does not occur. In other words, in the case of the seventh operation example, when the data in the selected cell is data “1”, nondestructive read can be performed.

On the other hand, when the data in the selected cell is data “0”, there is a possibility that by applying the negative-side read voltage Vrn lower than the first negative voltage side threshold voltage Vtpn, current flows, and the data in the selected cell changes to data “1”. In other words, in the case of the seventh operation example, when the data in the selected cell is data “0”, destructive read possibly occurs. Consequently, when the data in the selected cell is data “0”, there is a possibility that rewriting of data “0” is required to maintain the data in the selected cell after data is read from the selected cell.

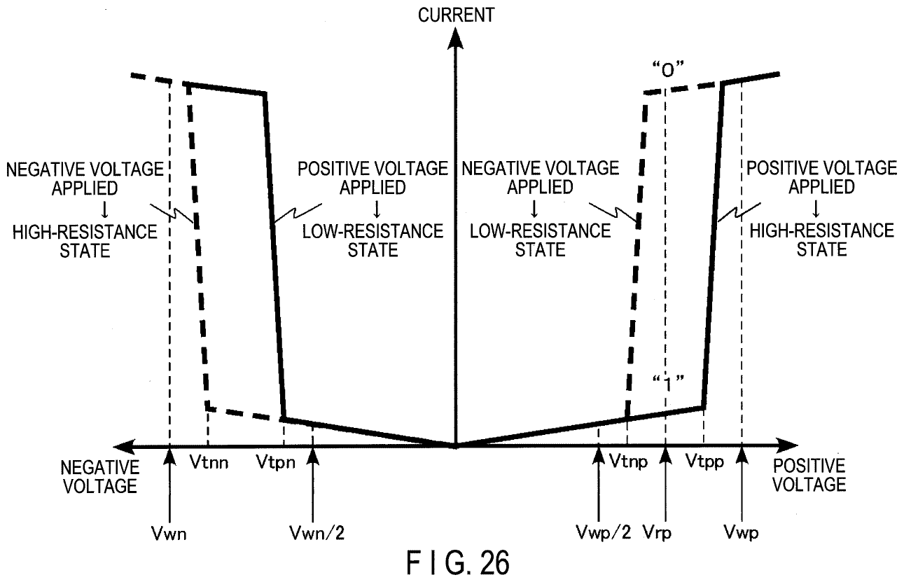

FIG. 26 is a diagram illustrating an eighth operation example of memory operation of the storage device in the third modification of the sixth embodiment. FIG. 26 shows a positive-side write voltage Vwp, a half voltage of the positive-side write voltage Vwp (Vwp/2), a negative-side write voltage Vwn, a half voltage of the negative-side write voltage Vwn (Vwn/2), and a positive-side read voltage Vrp when the memory operation is performed.

In the eighth operation example, the high-resistance state and the low-resistance state on the positive voltage side are used for the memory operation. In the eighth operation example, the positive-side read voltage Vrp is used as a read voltage.

When data “1” is written into the selected cell, the positive-side write voltage Vwp is applied to the second electrode 20. The positive-side write voltage Vwp is a voltage higher than the first positive voltage side threshold voltage Vtpp. By applying the positive-side write voltage Vwp to the second electrode 20, the high-resistance state is achieved on the positive voltage side, and data “1” is written into the selected cell.

When data “0” is written into the selected cell, the negative-side write voltage Vwn is applied to the second electrode 20. The negative-side write voltage Vwn is a voltage lower than the second negative voltage side threshold voltage Vtnn. By applying the negative-side write voltage Vwn to the second electrode 20, the low-resistance state is achieved on the positive voltage side, and data “0” is written into the selected cell.

In the eighth operation example, in the case where data stored in the selected cell is data “0” when data “1” is written into the selected cell, the current flows as long as the positive-side write voltage Vwp is higher than the second positive voltage side threshold voltage Vtnp even if it is lower than the first positive voltage side threshold voltage Vtpp. Accordingly, there is a possibility that data “1” can be written. Consequently, for example, by setting the positive-side write voltage Vwp to a voltage between the second positive voltage side threshold voltage Vtnp and the first positive voltage side threshold voltage Vtpp, a low power consumption and high reliability of the storage device can be achieved.

In the eighth operation example, in the case where data stored in the selected cell is data “1” when data “0” is written into the selected cell, the current flows as long as the negative-side write voltage Vwn is lower than the first negative voltage side threshold voltage Vtpn even if it is higher than the second negative voltage side threshold voltage Vtnn. Accordingly, there is a possibility that data “0” can be written. Consequently, for example, by setting the negative-side write voltage Vwn to a voltage between the second negative voltage side threshold voltage Vtnn and the first negative voltage side threshold voltage Vtpn, a low power consumption and high reliability of the storage device can be achieved.

Note that when the positive-side write voltage Vwp is applied to the selected cell, the voltage Vwp/2 is applied to the semi-selected cell. Note that when the negative-side write voltage Vwn is applied to the selected cell, the voltage Vwn/2 is applied to the semi-selected cell. The voltage Vwp/2 is lower than the second positive voltage side threshold voltage Vtnp. The voltage Vwn/2 is higher than the first negative voltage side threshold voltage Vtpn.

Consequently, even if the semi-selected cell is in the low-resistance state, the semi-selected leakage current flowing through the semi-selected cell can be prevented. Consequently, the memory element also functions as a switching element.

When the data in the selected cell is read, the positive-side read voltage Vrp is applied to the selected cell. By detecting change in current or change in potential caused by the difference in flowing current between the case of data “1” and the case of data “0”, the data in the selected cell can be determined.

Note that in the case of the eighth operation example, when the data in the selected cell is data “1”, data destruction due to application of the positive-side read voltage Vrp does not occur. In other words, in the case of the eighth operation example, when the data in the selected cell is data “1”, nondestructive read can be performed.

On the other hand, when the data in the selected cell is data “0”, there is a possibility that by applying the positive-side read voltage Vrp higher than the second positive voltage side threshold voltage Vtnp, current flows, and the data in the selected cell changes to data “1”. In other words, in the case of the eighth operation example, when the data in the selected cell is data “0”, destructive read possibly occurs. Consequently, when the data in the selected cell is data “0”, there is a possibility that rewriting of data “0” is required to maintain the data in the selected cell after data is read from the selected cell.

In each of the storage devices in the sixth embodiment and its modifications, the memory element of the memory cell MC has the switching function, and also has a function of storing information. The memory layer 60 performs the function of the switching layer 40 and the function of the resistive layer 50 in the first to fifth embodiments with a single layer. The memory layer 60 in the sixth embodiment has the switching function and the memory function with a single layer, thereby allowing the structure of the memory cell MC to be a simple structure.

The first electrode 10 and the second electrode 20 of the storage device in the sixth embodiment and its modifications have configurations similar to those of the first electrode 10 and the second electrode 20 in the first embodiment. Consequently, according to the sixth embodiment and its modifications, similar to the first embodiment, the storage device having excellent characteristics can be achieved. The first electrode 10 and the second electrode 20 of the storage device in the sixth embodiment and its modifications may have configurations similar to those of the first electrode 10 and the second electrode 20 in the second to fourth embodiments. Similar to the second to fourth embodiments, the storage device having excellent characteristics can be achieved.

Note that a plurality of current-voltage characteristics of the memory elements described in the sixth embodiment and its modifications can be achieved by adopting the memory layer 60 that has an appropriate chemical composition, for example.

In the first to fourth embodiments, description is made using the example of the magnetoresistive memory as the two-terminal storage device, and in the fifth embodiment, description is made using the example of the resistive memory as the storage device. Alternatively, the present invention is also applicable to other two-terminal storage devices. For example, the present invention is applicable to a phase change memory (PCM), or a ferroelectric random access memory (FeRAM).

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is

1. A storage device comprising:
a plurality of memory cells each including a first electrode, a second electrode, a third electrode, a switching layer, and a resistive layer, wherein
the second electrode is between the first and third electrodes,
the switching layer is between the first and second electrodes,
the resistive layer is between the second and third electrodes,
the switching layer includes:
an oxide, a nitride, or an oxynitride of at least one first element selected from a group consisting of aluminum, silicon, germanium, zirconium, yttrium, tantalum, lanthanum, cerium, titanium, hafnium, and magnesium,
at least one second element that is different from the first element and is selected from a group consisting of aluminum, zinc, tin, gallium, bismuth, and indium, and
at least one third element selected from a group consisting of tellurium, sulfur, selenium, and antimony,
at least one of the first and second electrodes includes a carbon layer, and
the carbon layer includes a first region that contacts the switching layer and includes at least one fourth element selected from a group consisting of silicon, aluminum, phosphorus, gallium, and germanium.

2. The storage device according to claim 1, wherein
in the first region, a ratio of an atomic concentration of the fourth element to a sum of atomic concentrations of carbon and the fourth element is 1% or more and 20% or less.

3. The storage device according to claim 1, wherein
the carbon layer further includes a second region,
the first region is between the second region and the switching layer, and
an atomic concentration of the fourth element in the second region is lower than an atomic concentration of the fourth element in the first region.

4. The storage device according to claim 3, wherein
a first thickness of the first region in a first direction from the first electrode toward the second electrode is less than a second thickness of the second region in the first direction.

5. The storage device according to claim 3, wherein
in the second region, a ratio of the atomic concentration of the fourth element to a sum of atomic concentrations of carbon and the fourth element is 0% or more and 5% or less.

6. The storage device according to claim 1, wherein
the first region includes six-membered ring structures of carbon.

7. The storage device according to claim 1, wherein
the first and second electrodes include the carbon layer.

8. The storage device according to claim 1, wherein
at least one of the first and second electrodes includes a metal layer, and
the carbon layer is between the metal layer and the switching layer.

9. The storage device according to claim 1, wherein
the switching layer includes a compound of the second and third elements.

10. The storage device according to claim 1, wherein
the switching layer further includes carbon, boron, or phosphorus.

11. The storage device according to claim 1, wherein
the resistive layer includes a magnetic tunnel junction.

12. The storage device according to claim 1, wherein
an electrical resistance of the resistive layer changes upon applying a predetermined voltage thereto, and
the switching layer has nonlinear current-voltage characteristics as a result of which current through the switching layer rises at a specific threshold voltage.

13. The storage device according to claim 1, further comprising:
a plurality of first lines; and
a plurality of second lines that intersect the first lines, wherein
the memory cells are formed at intersections of the first lines with the second lines.

14. A storage device comprising:
a plurality of memory cells each including a first electrode, a second electrode, and a memory layer between the first and second electrodes, wherein
the memory layer includes:
an oxide, a nitride, or an oxynitride of at least one first element selected from a group consisting of aluminum, silicon, germanium, zirconium, yttrium, tantalum, lanthanum, cerium, titanium, hafnium, and magnesium,
at least one second element that is different from the first element and is selected from a group consisting of aluminum, zinc, tin, gallium, bismuth, and indium, and
at least one third element selected from a group consisting of tellurium, sulfur, selenium, and antimony,
at least one of the first and second electrodes includes a carbon layer, and
the carbon layer includes a first region that contacts the memory layer and includes at least one fourth element selected from a group consisting of silicon, aluminum, phosphorus, gallium, and germanium.

15. The storage device according to claim 14, wherein
in the first region, a ratio of an atomic concentration of the fourth element to a sum of atomic concentrations of carbon and the fourth element is 1% or more and 20% or less.

16. The storage device according to claim 14, wherein
the carbon layer further includes a second region,
the first region is between the second region and the memory layer, and
an atomic concentration of the fourth element in the second region is lower than an atomic concentration of the fourth element in the first region.

17. The storage device according to claim 16, wherein
a first thickness of the first region in a first direction from the first electrode toward the second electrode is less than a second thickness of the second region in the first direction.

18. The storage device according to claim 16, wherein
in the second region, a ratio of the atomic concentration of the fourth element to a sum of atomic concentrations of carbon and the fourth element is 0% or more and 5% or less.

19. The storage device according to claim 14, wherein
the first region includes six-membered ring structures of carbon.

20. The storage device according to claim 14, wherein
the first and second electrodes include the carbon layer.

21. The storage device according to claim 14, wherein
at least one of the first and second electrodes includes a metal layer, and
the carbon layer is between the metal layer and the memory layer.

22. The storage device according to claim 14, wherein
the memory layer includes a compound of the second and third elements.

23. The storage device according to claim 14, wherein
the memory layer further includes carbon, boron, or phosphorus.

24. The storage device according to claim 14, wherein
the memory layer has nonlinear current-voltage characteristics as a result of which current through the memory layer rises at a specific threshold voltage, and the threshold voltage changes upon applying a predetermined voltage thereto.

25. The storage device according to claim 14, further comprising:
a plurality of first lines; and
a plurality of second lines that intersect the first lines, wherein
the memory cells are formed at intersections of the first lines with the second lines.
